(19) United States
(12) Patent Application Publication
(10) Pub. No.: US 2013/0143018 A1
(43) Pub. Date: Jun. 6, 2013

(54) Coated Polymer Films

(71) Applicant: Sabic Innovative Plastics IP B.V., Bergen op Zoom (NL)

(72) Inventors: Daniel Qi Tan, Rexford, NY (US); Anne Bolvari, West Chester, PA (US); Ri-an Zhao, Niskayuna, NY (US)

(73) Assignee: Sabic Innovative Plastics IP B.V., Bergen op Zoom (NL)

(21) Appl. No.: 13/691,008

(22) Filed: Nov. 30, 2012

Related U.S. Application Data
(60) Provisional application No. 61/566,353, filed on Dec. 2, 2011.

(51) Int. Cl. C23C 16/34; H01B 3/00; C23C 16/40

(52) U.S. Cl. CPC C23C 16/342; C23C 16/402; C23C 16/345; C23C 16/403; C23C 16/405; C23C 16/409; H01B 3/00
USPC 428/216; 427/248.1; 427/569; 427/576; 427/579; 427/255.28; 427/255.36; 427/255.32; 427/255.37; 428/336; 428/697; 428/701; 428/702; 428/522; 428/500; 428/475.5; 428/480; 428/473.5; 428/422; 428/523; 428/412; 428/419; 428/521; 428/524; 428/421; 428/446; 428/451; 428/337

(57) ABSTRACT

Coated polymer compositions having improved dielectric strength are disclosed. The coated polymer compositions can comprise a polymer substrate and an inorganic material. This abstract is intended as a scanning tool for purposes of searching in the particular art and is not intended to be limiting of the present invention.

### CROSS-REFERENCE TO RELATED APPLICATIONS

This Application claims the benefit of U.S. Provisional Application No. 61/566,353, filed on Dec. 2, 2011; which is incorporated herein by reference in its entirety.

### BACKGROUND

1. Technical Field

The present disclosure relates to dielectric materials, and specifically to polymer compositions having improved dielectric properties.

2. Technical Background

Dielectric materials are nonconductive, electrically insulating materials that are commonly used in electronics and energy related devices. Capacitors are electrical components that can hold or store electrical charge in layers of dielectric materials within the capacitor. These dielectric materials typically comprise a polymer. The energy density of a capacitor is related to the dielectric properties and electrical breakdown strength of the dielectric materials therein. Thus, the energy density of conventional capacitors is frequently limited by the dielectric properties and dielectric strength of the polymers used in the dielectric layers.

Accordingly, there remains a need for polymeric dielectric materials having improved dielectric properties and dielectric strength. These needs and other needs are satisfied by the compositions and methods of the present disclosure.

### SUMMARY

In accordance with the purpose(s) of the invention, as embodied and broadly described herein, this disclosure, in one aspect, relates to dielectric materials, and specifically to polymer compositions having improved dielectric properties.

In one aspect, the present disclosure provides a coated polymer composition, comprising a polymer substrate and an inorganic material deposited on at least one surface thereof, wherein the coated polymer composition has an improved dielectric strength as compared to an uncoated polymer substrate of the same composition.

In another aspect, the present disclosure provides a capacitor comprising a coated polymer composition as described herein.

In another aspect, the present disclosure provides a method of preparing a coated polymer composition, the method comprising depositing an inorganic material on at least a portion of one surface of a polymer substrate, such that the resulting coated polymer composition has an improved dielectric strength over the polymer substrate itself.

Additional aspects of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE FIGURES

FIG. 1 illustrates the improvement in breakdown strength obtainable from deposition of a silica film on a polyetherimide substrate, in accordance with various aspects of the present disclosure.

FIG. 2 illustrates the improvement in DC breakdown strength obtainable from deposition of a silica film on a polyetherimide substrate, in accordance with various aspects of the present disclosure.

FIG. 3 illustrates the improvement in breakdown strength obtainable from deposition of a silicon nitride (SiNₓ) film on a polyetherimide substrate, in accordance with various aspects of the present disclosure.

FIG. 4 is a photomicrograph of a polyetherimide film coated with a SiNₓ film, in accordance with various aspects of the present disclosure.

FIG. 5 illustrates stress-strain curves for silica coated polyetherimide substrates, in accordance with various aspects of the present disclosure.

FIG. 6 shows coating schemes typical of the claimed invention. As shown, various combinations of High-k and Low-k layers can be added to the polymer substrate.

FIG. 7 shows data from reactive sputtering of Ta₂O₅ under different O₂ flows, wherein the x axis represents the breakdown strength in kV/mm, and wherein the y axis represents the probability of failure.

FIG. 8 shows data from magnetron sputter coating of SrTiO₃ on Ultem 1000. The SrTiO₃ coating was applied by radio frequency (RF) magnetron sputtering at 10% O₂, wherein the x axis represents the breakdown strength in kV/mm, and wherein the y axis represents the probability of failure.

FIG. 9 shows data from a high-K (dielectric constant) TiO₂ coating effects on Ultem 1000, wherein the x axis represents the breakdown strength in kV/mm, and wherein the y axis represents the probability of failure.

FIG. 10 shows data from reactive sputtering under different O₂ flow.

FIG. 11 shows data from a SiO₂ coating deposited via PECVD versus sputtering. Oxygen flow rate was 30 sccm and 2% SiH₄ was diluted in helium. PECVD coating time is 46, 92, and 138 seconds for 50, 100, and 150 nm coatings of SiO₂, respectively.

FIG. 12 shows the data of a 1-side asymmetric Low-k/High-k coating combination on Ultem 1000. 50 nm of Ta₂O₅ and 100 nm of SiO₂ served as the inorganic layers added to the film using a planar sputtering method, wherein the x axis represents the breakdown strength in kV/mm, and wherein the y axis represents the probability of failure.

FIG. 13 shows the data of a 1-side asymmetric Low-k/High-k coating combination on Ultem 1000. 100 nm of Ta₂O₅ and 100 nm of SiO₂ served as the inorganic layers added to the film using RF magnetron sputtering method, wherein the x axis represents the breakdown strength in kV/mm, and wherein the y axis represents the probability of failure.

FIG. 14 shows the data of a 1-side asymmetric Low-k/High-k coating combination on Ultem 1000. 100 nm of SrTiO₃ and 100 nm of SiO₂ served as the inorganic layers added to the film using RF magnetron sputtering method, wherein the x axis represents the breakdown strength in kV/mm, and wherein the y axis represents the probability of failure.

FIG. 15 shows the data of a 2-side symmetric High-k/Low-k coating combination on Ultem 1000. Double coatings of 50 nm of Ta₂O₅ and 100 nm of SiO₂ served as the inorganic layers added to the film, wherein the x axis represents the breakdown strength in kV/mm, and wherein the y axis represents the probability of failure.

FIG. 16 shows the data of a 2-side symmetric High-k/Low-k coating combination on Ultem 1000 with a comparatively thicker coating than the example in FIG. 15. Double coatings of 100 nm of Ta₂O₅ and 100 nm of SiO₂ served as the inorganic layers added to the film, wherein the x axis represents the breakdown strength in kV/mm, and wherein the y axis represents the probability of failure.

FIG. 17 shows the data of a 2-side symmetric High-k/Low-k coating combination on Ultem 1000. Double coatings of 100 nm of SrTiO₃ and 50 nm of SiO₂ served as the inorganic layers added to the film, wherein the x axis represents the breakdown strength in kV/mm, and wherein the y axis represents the probability of failure.

FIG. 18 shows the data of asymmetric Low-k/High-k coating combination on Ultem 1000. Both sides of a 5 micron Ultem 1000 film were coated with 50 nm SiO₂ and a single side was coated with SrTiO₃, wherein the x axis represents the breakdown strength in kV/mm, and wherein the y axis represents the probability of failure.

FIG. 19 shows the coating effect on Ultem 1000 composite. Ultem-30% BaTiO₃ composites were coated with 100 nm of SiO₂, wherein the x axis represents the breakdown strength in kV/mm, and wherein the y axis represents the probability of failure.

FIG. 20 shows the coating effect of TiO₂ on Ultem 1000. TiO₂ was applied by reactive sputtering in 18% O₂, RF in 7% O₂, or RF in no O₂, wherein the x axis represents the breakdown strength in kV/mm, and wherein the y axis represents the probability of failure.

FIG. 21 shows High-k coating on polycarbonate films from Lexan 151. The graph shows the coating effect of 50 nm Ta₂O₅ on 10 μm polycarbonate, wherein the x axis represents the breakdown strength in kV/mm, and wherein the y axis represents the probability of failure.

FIG. 22 shows the effect of High-k coating on polycarbonate films. Ta₂O₅ coating was applied as either 100 nm or 50 nm layers by sputtering on a 10 μm polycarbonate film, wherein the x axis represents the breakdown strength in kV/mm, and wherein the y axis represents the probability of failure.

### DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

All publications mentioned herein are incorporated herein by reference to disclose and describe the methods and/or materials in connection with which the publications are cited.

### DEFINITIONS

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, example methods and materials are now described.

As used in the specification and the appended claims, the singular forms “a,” “an” and “the” include plural referents unless the context clearly dictates otherwise. Thus, for example, reference to “a ketone” includes mixtures of two or more ketones.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “dielectric strength” and “breakdown strength” are used interchangeably and refer to the maximum electric stress a material can withstand before breakdown. The “dielectric strength” and “breakdown strength” can, for example, be measured in V/μm or kV/mm.

As used herein, the term “high dielectric constant” refers to a material, such as an inorganic material, that has a dielectric constant of 10 or above. Materials with a high dielectric constant include, but are not limited to, TiO₂, Ta₂O₅, and SrTiO₃.

As used herein, the term “low dielectric constant” refers to a material, such as an inorganic material, that has a dielectric constant of less than 10. Materials with a low dielectric constant include, but are not limited to, SiO₂ and SiNₓ.

As used herein, the terms “optional” or “optionally” means that the subsequently described event or circumstance can or can not occur, and that the description includes instances where said event or circumstance occurs and instances where it does not. For example, the phrase “optionally substituted alkyl” means that the alkyl group can or can not be substituted and that the description includes both substituted and unsubstituted alkyl groups.

As used herein, the terms “polymer substrate” or the like terms refer to a material comprising a polymer. The polymer substrate can have any shape. For example, the polymer substrate can be flat or curved. Thus, polymer substrates include, but are not limited to, films and wires.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds can not be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific aspect or combination of aspects of the methods of the invention.

References in the specification and concluding claims to parts by weight, of a particular element or component in a composition or article, denote the weight relationship between the element or component and any other elements or components in the composition or article for which a part by weight is expressed. Thus, in a compound containing 2 parts by weight of component X and 5 parts by weight of component Y, X and Y are present at a weight ratio of 2:5, and are present in such ratio regardless of whether additional components are contained in the compound.

A weight percent of a component, unless specifically stated to the contrary, is based on the total weight of the formulation or composition in which the component is included.

A residue of a chemical species, as used in the specification and concluding claims, refers to the moiety that is the resulting product of the chemical species in a particular reaction scheme or subsequent formulation or chemical product, regardless of whether the moiety is actually obtained from the chemical species. Thus, an ethylene glycol residue in a polyester refers to one or more —OCH₂CH₂O— units in the polyester, regardless of whether ethylene glycol was used to prepare the polyester. Similarly, a sebacic acid residue in a polyester refers to one or more —CO(CH₂)₈CO— moieties in the polyester, regardless of whether the residue is obtained by reacting sebacic acid or an ester thereof to obtain the polyester.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

As briefly described above, a capacitor is an electrical component that stores electrical charge in one or more dielectric layers. In many capacitors, the dielectric layer comprises a polymer. The energy density of a dielectric polymer material is a measure of the electrical charge carrying capability of the material, and is related to the dielectric strength and the dielectric constant of the material. In one aspect, the present invention realizes that the dielectric strength of a material can be increased with little or no change to the dielectric constant of the material. In various aspects, such a benefit can be realized by applying a thin inorganic layer, such as, a thin layer of silicon dioxide or glass to the surface of a polymer substrate. In one aspect, the layer of inorganic material is typically thinner than the polymer substrate.

In one aspect, the present disclosure provides a method for increasing the breakdown voltage of a polymer material by applying a thin layer of an inorganic material on its surface. In another aspect, the present disclosure provides a dielectric polymer material having improved dielectric properties and dielectric strength as compared to conventional polymer materials.

1. Polymer Substrate

The polymer substrate of the present invention can comprise any polymeric material suitable for use as a dielectric material. In another aspect, the polymer substrate can comprise any polymeric material suitable for use in a capacitor. In one aspect, the polymer substrate can comprise a high temperature polymer. In other aspects, the polymer substrate can comprise a polar polymer, a non-polar polymer, or a combination thereof. In yet other aspects, the polymer substrate can comprise an olefin, a polyester, a fluorocarbon, or a combination thereof. In various aspects, the polymer substrate can comprise a polymethylmethacrylate, polyvinyl chloride, nylon, polyethylene terephthalate, polyimide, polyetherimide, polytetrafluoroethylene, polyethylene, ultra-high-molecular-weight polyethylene, polypropylene, polycarbonate, polystyrene, polysulfone, polyamides, aromatic polyamids, polyphenylene sulfide, polybutylene terephthalate, polyphenylene oxide, acrylonitrile butadiene styrene, polyetgerketone, polyetheretherketone, polyoxymethylene plastic, or a combination thereof, or a combination thereof. In other aspects, the polymer substrate can comprise a polyethylene terephthalate, an Ultem® polyetherimide, a Kapton® polyimide, polyvinylidene fluoride, cellulose acetate, or a combination thereof.

In one aspect, the polymer substrate comprises a polyetherimides. In another aspect, the polymer substrate comprises a polymethylmethacrylate. In another aspect, the polymer substrate comprises a polyvinyl chloride. In another aspect, the polymer substrate comprises a nylon. In another aspect, the polymer substrate comprises a polyethylene terephthalate. In another aspect, the polymer substrate comprises a polyimide. In another aspect, the polymer substrate comprises a polytetrafluoroethylene. In another aspect, the polymer substrate comprises a polyethylene. In another aspect, the polymer substrate comprises a polypropylene. In another aspect, the polymer substrate comprises a polycarbonate. In another aspect, the polymer substrate comprises a polystyrene. In another aspect, the polymer substrate comprises a polysulfone. In other aspects, the polymer substrate can specifically not include any one of more of the individual polymers or types of components recited herein. In another aspect, the polymer substrate does not comprise a cyanoresin. In another aspect, the polymer substrate does not comprise a cyano modified polymer such as a cyano-modified polyetherimide, and/or a polyetherimide derived from a cyano-bisphenol. In another aspect, the polymer substrate comprises a polyvinylidene fluoride. In yet another aspect, the polymer substrate comprises a cellulose acetate.

In still other aspects, the polymer substrate can comprise a nanocomposite film, for example, wherein the polymer is loaded with a plurality of nanoparticles. In other aspects, the polymer substrate can comprise one or multiple layers of the same or varying composition. In one aspect, the polymer substrate comprises a single layer. In another aspect, the polymer substrate comprises a plurality of layers, for example, two, three, four, or more layers. The composition of the polymer substrate or any portion thereof can also comprise any polymeric material not specifically recited herein. Polymer materials are commercially available, and one of skill in the art in possession of this disclosure could readily select an appropriate polymer substrate material.

The thickness of the polymer substrate can vary, and the present invention is not intended to be limited to any particular polymer substrate thickness. In various aspects, the thickness of the polymer substrate can range from about 1 micrometer to about 1,000 micrometers, for example, about 1, 2, 3, 4, 5, 7, 9, 10, 15, 20, 25, 30, 40, 50, 75, 100, 150, 200, 250, 300, 350, 400, 500, 600, 750, 800, 900, or 1,000 micrometers. In another aspect, the thickness of the polymer substrate can range from about 1 micrometer to about 500 micrometer, for example, about 1, 2, 3, 4, 5, 6, 7, 8, 9, 10, 15, 20, 25, 30, 35, 40, 50, 60, 70, 80, 90, 100, 125, 150, 200, 250, 300, 350, 400, 450, or 500 micrometers. In other aspects, the polymer substrate can be less than about 1 micrometer or greater than about 1,000 micrometers in thickness. For example, the thickness of the polymer substrate can be about 5 micrometers to about 20 micrometers. For example, the thickness of the polymer substrate can be about 5 micrometers. In another example, the thickness of the polymer substrate can be less than 10, 9, 8, 7, 6, 5, 4, 3, 2, or 1 micrometers. For example, the thickness of the polymer substrate can be less than 5, 4, 3, 2, or 1 micrometers.

In another aspect, the polymer substrate can comprise additional layers or materials, such as, for example, reinforcing and/or adhesive materials, on one or both sides of the polymer substrate.

In yet another aspect, the polymer substrate is a planar material, such as, for example, a thin film.

(1) Polyetherimides

As disclosed, the polymer substrate can comprise polyetherimides and polyetherimides copolymers. The polyetherimide can be selected from (i) polyetherimidehomopolymers, e.g., polyetherimides, (ii) polyetherimide co-polymers, e.g., polyetherimidesulfones, and (iii) combinations thereof. Polyetherimides are known polymers and are sold by SABIC Innovative Plastics under the ULTEM®*, EXTEM®*, and Siltem* brands (Trademark of SABIC Innovative Plastics IP B.V.).

In an aspect, the polyetherimides can be of formula (1):

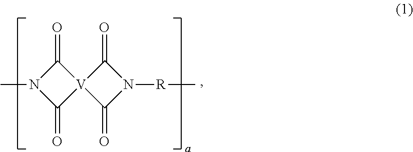

wherein a is more than 1, for example 10 to 1,000 or more, or more specifically 10 to 500. In one example, n can be 10-100, 10-75, 10-50 or 10-25.

The group V in formula (1) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations comprising at least one of the foregoing. Suitable additional substitutions include, but are not limited to, ethers, amides, esters, and combinations comprising at least one of the foregoing.

The R group in formula (1) includes but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (2):

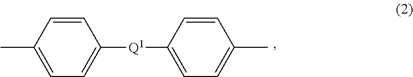

wherein Q1 includes but is not limited to a divalent moiety such as —O—, —S—, —C(O)—, —SO₂—, —SO—, —CyH2y- (y being an integer from 1 to 5), and halogenated derivatives thereof, including perfluoroalkylene groups.

In an embodiment, linkers V include but are not limited to tetravalent aromatic groups of formula (3):

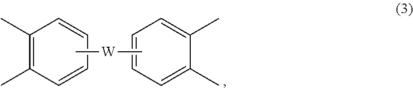

wherein W is a divalent moiety including —O—, —SO₂—, or a group of the formula —O—Z—O— wherein the divalent bonds of the —O— or the —O—Z—O— group are in the 3,3′,3,4′,4,3′, or the 4,4′ positions, and wherein Z includes, but is not limited, to divalent groups of formulas (4):

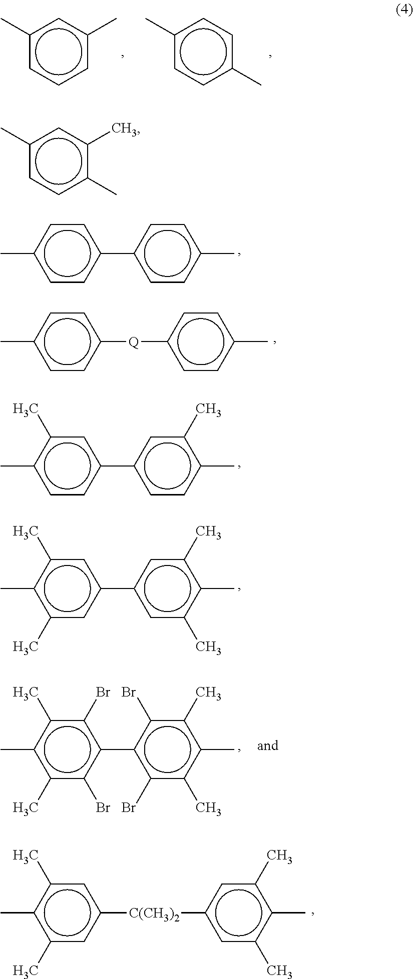

wherein Q includes, but is not limited to a divalent moiety including —O—, —S—, —C(O), —SO₂−, —SO—, —C_{y}H_{2y}— (y being an integer from 1 to 5), and halogenated derivatives thereof, including perfluoroalkylene groups.

In an aspect, the polyetherimide comprise more than 1, specifically 10 to 1,000, or more specifically, 10 to 500 structural units, of formula (5):

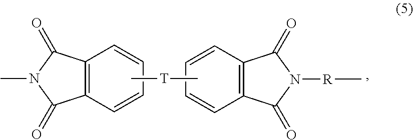

wherein T is —O— or a group of the formula —O—Z—O— wherein the divalent bonds of the —O— or the —O—Z—O— group are in the 3,3′,3,4′,4,3′, or the 4,4′ positions; Z is a divalent group of formula (3) as defined above; and R is a divalent group of formula (2) as defined above.

In another aspect, the polyetherimidesulfones are polyetherimides comprising ether groups and sulfone groups wherein at least 50 mole % of the linkers V and the groups R in formula (1) comprise a divalent arylenesulfone group. For example, all linkers V, but no groups R, can contain an arylenesulfone group; or all groups R but no linkers V can contain an arylenesulfone group; or an arylenesulfone can be present in some fraction of the linkers V and R groups, provided that the total mole fraction of V and R groups containing an aryl sulfone group is greater than or equal to 50 mole %.

Even more specifically, polyetherimidesulfones can comprise more than 1, specifically 10 to 1,000, or more specifically, 10 to 500 structural units of formula (6):

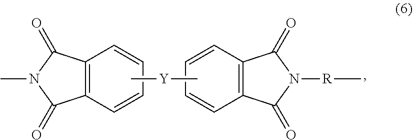

wherein Y is —O—, —SO₂—, or a group of the formula —O—Z—O— wherein the divalent bonds of the —O—, SO₂—, or the —O—Z—O— group are in the 3,3′,3,4′,4,3′, or the 4,4′ positions, wherein Z is a divalent group of formula (3) as defined above and R is a divalent group of formula (2) as defined above, provided that greater than 50 mole % of the sum of moles Y+moles R in formula (2) contain —SO₂— groups.

It is to be understood that the polyetherimides and polyetherimidesulfones can optionally comprise linkers V that do not contain ether or ether and sulfone groups, for example linkers of formula (7):

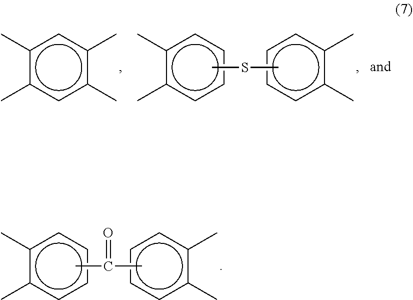

Imide units containing such linkers are generally be present in amounts ranging from 0 to 10 mole % of the total number of units, specifically 0 to 5 mole %. In one embodiment no additional linkers V are present in the polyetherimides and polyetherimidesulfones.

In another aspect, the polyetherimide comprises 10 to 500 structural units of formula (5) and the polyetherimidesulfone contains 10 to 500 structural units of formula (6).

Polyetherimides and polyetherimidesulfones can be prepared by any suitable process. In one embodiment, polyetherimides and polyetherimide copolymers include polycondensation polymerization processes and halo-displacement polymerization processes.

Polycondensation methods can include a method for the preparation of polyetherimides having structure (1) is referred to as the nitro-displacement process (X is nitro in formula (8)). In one example of the nitro-displacement process, N-methyl phthalimide is nitrated with 99% nitric acid to yield a mixture of N-methyl-4-nitrophthalimide (4-NPI) and N-methyl-3-nitrophthalimide (3-NPI). After purification, the mixture, containing approximately 95 parts of 4-NPI and 5 parts of 3-NPI, is reacted in toluene with the disodium salt of bisphenol-A (BPA) in the presence of a phase transfer catalyst. This reaction yields BPA-bisimide and NaNO₂ in what is known as the nitro-displacement step. After purification, the BPA-bisimide is reacted with phthalic anhydride in an imide exchange reaction to afford BPA-dianhydride (BPADA), which in turn is reacted with a diamine such as meta-phenylene diamine (MPD) in ortho-dichlorobenzene in an imidization-polymerization step to afford the product polyetherimide.

Other diamines are also possible. Examples of suitable diamines include: m-phenylenediamine; p-phenylenediamine; 2,4-diaminotoluene; 2,6-diaminotoluene; m-xylylenediamine; p-xylylenediamine; benzidine; 3,3′-dimethylbenzidine; 3,3′-dimethoxybenzidine; 1,5-diaminonaphthalene; bis(4-aminophenyl)methane; bis(4-aminophenyl)propane; bis(4-aminophenyl)sulfide; bis(4-aminophenyl)sulfone; bis(4-aminophenyl)ether; 4,4′-diaminodiphenylpropane; 4,4′-diaminodiphenylmethane(4,4′-methylenedianiline); 4,4′-diaminodiphenylsulfide; 4,4′-diaminodiphenylsulfone; 4,4′-diaminodiphenylether(4,4′-oxydianiline); 1,5-diaminonaphthalene; 3,3′ dimethylbenzidine; 3-methylheptamethylenediamine; 4,4-dimethylheptamethylenediamine; 2,2′,3,3′-tetrahydro-3,3,3′,3′-tetramethyl-1,1′-spirobi[1H-indene]-6,6′-diamine; 3,3′,4,4′-tetrahydro-4,4,4′,4′-tetramethyl-2,2′-spirobi[2H-1-benzo-pyran]-7,7′-diamine; 1,1′-bis[1-amino-2-methyl-4-phenyl]cyclohexane, and isomers thereof as well as mixtures and blends comprising at least one of the foregoing. In one embodiment, the diaminesare specifically aromatic diamines, especially m- and p-phenylenediamine and mixtures comprising at least one of the foregoing.

Suitable dianhydrides that can be used with the diamines include and are not limited to 2,2-bis[4-(3,4-dicarboxyphenoxy)phenyl]propane dianhydride; 4,4′-bis(3,4-dicarboxyphenoxy)diphenyletherdianhydride; 4,4′-bis(3,4-dicarboxyphenoxy)diphenylsulfidedianhydride; 4,4′-bis(3,4-dicarboxyphenoxy)benzophenonedianhydride; 4,4′-bis(3,4-dicarboxyphenoxy)diphenylsulfonedianhydride; 2,2-bis[4-(2,3-dicarboxyphenoxy)phenyl]propane dianhydride; 4,4′-bis(2,3-dicarboxyphenoxy)diphenyletherdianhydride; 4,4′-bis(2,3-dicarboxyphenoxy)diphenylsulfidedianhydride; 4,4′-bis(2,3-dicarboxyphenoxy)benzophenonedianhydride; 4,4′-bis(2,3-dicarboxyphenoxy)diphenylsulfonedianhydride; 4-(2,3-dicarboxyphenoxy)-4′-(3,4-dicarboxyphenoxy)diphenyl-2,2-propane dianhydride; 4-(2,3-dicarboxyphenoxy)-4′-(3,4-dicarboxyphenoxy)diphenyletherdianhydride; 4-(2,3-dicarboxyphenoxy)-4′-(3,4-dicarboxyphenoxy)diphenylsulfide dianhydride; 4-(2,3-dicarboxyphenoxy)-4′-(3,4-dicarboxyphenoxy)benzophenonedianhydride; 4-(2,3-dicarboxyphenoxy)-4′-(3,4-dicarboxyphenoxy)diphenylsulfone dianhydride; 1,3-bis(2,3-dicarboxyphenoxy)benzene dianhydride; 1,4-bis(2,3-dicarboxyphenoxy)benzene dianhydride; 1,3-bis(3,4-dicarboxyphenoxy)benzene dianhydride; 1,4-bis(3,4-dicarboxyphenoxy)benzene dianhydride; 3,3′,4,4′-diphenyl tetracarboxylicdianhydride; 3,3′,4,4′-benzophenonetetracarboxylic dianhydride; naphthalicdianhydrides, such as 2,3,6,7-naphthalic dianhydride, etc.; 3,3′,4,4′-biphenylsulphonictetracarboxylic dianhydride; 3,3′,4,4′-biphenylethertetracarboxylic dianhydride; 3,3′,4,4′-dimethyldiphenylsilanetetracarboxylic dianhydride; 4,4′-bis(3,4-dicarboxyphenoxy)diphenylsulfidedianhydride; 4,4′-bis(3,4-dicarboxyphenoxy)diphenylsulphonedianhydride; 4,4′-bis(3,4-dicarboxyphenoxy)diphenylpropanedianhydride; 3,3′,4,4′-biphenyltetracarboxylic dianhydride; bis(phthalic)phenylsulphineoxidedianhydride; p-phenylene-bis(triphenylphthalic)dianhydride; m-phenylene-bis(triphenylphthalic)dianhydride; bis(triphenylphthalic)-4,4′-diphenylether dianhydride; bis(triphenylphthalic)-4,4′-diphenylmethane dianhydride; 2,2′-bis(3,4-dicarboxyphenyl)hexafluoropropanedianhydride; 4,4′-oxydiphthalic dianhydride; pyromelliticdianhydride; 3,3′,4,4′-diphenylsulfonetetracarboxylic dianhydride; 4′,4′-bisphenol A dianhydride; hydroquinone diphthalic dianhydride; 6,6′-bis(3,4-dicarboxyphenoxy)-2,2′,3,3′-tetrahydro-3,3,3′,3′-tetramethyl-1-1,1′-spirobi[1H-indene]dianhydride; 7,7′-bis(3,4-dicarboxyphenoxy)-3,3′,4,4′-tetrahydro-4,4,4′,4′-tetramethyl-1-2,2′-spirobi[2H-1-benzopyran]dianhydride; 1,1′-bis[1-(3,4-dicarboxyphenoxy)-2-methyl-4-phenyl]cyclohexane dianhydride; 3,3′,4,4′-diphenylsulfonetetracarboxylic dianhydride; 3,3′,4,4′-diphenylsulfidetetracarboxylic dianhydride; 3,3′,4,4′-diphenylsulfoxidetetracarboxylic dianhydride; 4,4′-oxydiphthalic dianhydride; 3,4′-oxydiphthalic dianhydride; 3,3′-oxydiphthalic dianhydride; 3,3′-benzophenonetetracarboxylic dianhydride; 4,4′-carbonyldiphthalic dianhydride; 3,3′,4,4′-diphenylmethanetetracarboxylic dianhydride; 2,2-bis(4-(3,3-dicarboxyphenyl)propane dianhydride; 2,2-bis(4-(3,3-dicarboxyphenyl)hexafluoropropanedianhydride; (3,3′,4,4′-diphenyl)phenylphosphinetetracarboxylicdianhydride; (3,3′,4,4′-diphenyl)phenylphosphineoxidetetracarboxylicdianhydride; 2,2′-dichloro-3,3′,4,4′-biphenyltetracarboxylic dianhydride; 2,2′-dimethyl-3,3′,4,4′-biphenyltetracarboxylic dianhydride; 2,2′-dicyano-3,3′,4,4′-biphenyltetracarboxylic dianhydride; 2,2′-dibromo-3,3′,4,4′-biphenyltetracarboxylic dianhydride; 2,2′-diiodo-3,3′,4,4′-biphenyltetracarboxylic dianhydride; 2,2′-ditrifluoromethyl-3,3′,4,4′-biphenyltetracarboxylic dianhydride; 2,2′-bis(1-methyl-4-phenyl)-3,3′,4,4′-biphenyltetracarboxylic dianhydride; 2,2′-bis(1-trifluoromethyl-2-phenyl)-3,3′,4,4′-biphenyltetracarboxylic dianhydride; 2,2′-bis(1-trifluoromethyl-3-phenyl)-3,3′,4,4′-biphenyltetracarboxylic dianhydride; 2,2′-bis(1-trifluoromethyl-4-phenyl)-3,3′,4,4′-biphenyltetracarboxylic dianhydride; 2,2′-bis(1-phenyl-4-phenyl)-3,3′,4,4′-biphenyltetracarboxylic dianhydride; 4,4′-bisphenol A dianhydride; 3,4′-bisphenol A dianhydride; 3,3′-bisphenol A dianhydride; 3,3′,4,4′-diphenylsulfoxidetetracarboxylic dianhydride; 4,4′-carbonyldiphthalic dianhydride; 3,3′,4,4′-diphenylmethanetetracarboxylic dianhydride; 2,2′-bis(1,3-trifluoromethyl-4-phenyl)-3,3′,4,4′-biphenyltetracarboxylic dianhydride, and all isomers thereof, as well as combinations of the foregoing.

Halo-displacement polymerization methods for making polyetherimides and polyetherimidesulfones include and are not limited to, the reaction of a bis(phthalimide) for formula (8):

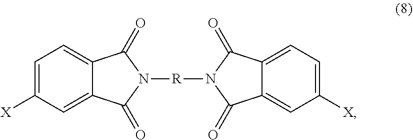

wherein R is as described above and X is a nitro group or a halogen. Bis-phthalimides (8) can be formed, for example, by the condensation of the corresponding anhydride of formula (9):

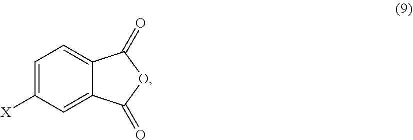

wherein X is a nitro group or halogen, with an organic diamine of the formula (10):

H₂N—R—NH₂ (10),

wherein R is as described above.

Illustrative examples of amine compounds of formula (10) include: ethylenediamine, propylenediamine, trimethylenediamine, diethylenetriamine, triethylenetetramine, hexamethylenediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2,2-dimethylpropylenediamine, N-methyl-bis(3-aminopropyl)amine, 3-methoxyhexamethylenediamine, 1,2-bis(3-aminopropoxy)ethane, bis(3-aminopropyl) sulfide, 1,4-cyclohexanediamine, bis-(4-aminocyclohexyl)methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, bis(4-aminophenyl)methane, bis(2-chloro-4-amino-3,5-diethylphenyl)methane, bis(4-aminophenyl) propane, 2,4-bis(b-amino-t-butyl) toluene, bis(p-b-amino-t-butylphenyl)ether, bis(p-b-methyl-o-aminophenyl)benzene, bis(p-b-methyl-o-aminopentyl)benzene, 1,3-diamino-4-isopropylbenzene, bis(4-aminophenyl)ether and 1,3-bis(3-aminopropyl) tetramethyldisiloxane. Mixtures of these amines can be used. Illustrative examples of amine compounds of formula (10) containing sulfone groups include but are not limited to, diaminodiphenylsulfone (DDS) and bis(aminophenoxy phenyl) sulfones (BAPS). Combinations comprising any of the foregoing amines can be used.

The polyetherimides can be synthesized by the reaction of the bis(phthalimide)(8) with an alkali metal salt of a dihydroxy substituted aromatic hydrocarbon of the formula HO—V—OH wherein V is as described above, in the presence or absence of phase transfer catalyst. Suitable phase transfer catalysts are disclosed in U.S. Pat. No. 5,229,482, which is incorporated herein by reference in its entirety. Specifically, the dihydroxy substituted aromatic hydrocarbon a bisphenol such as bisphenol A, or a combination of an alkali metal salt of a bisphenol and an alkali metal salt of another dihydroxy substituted aromatic hydrocarbon can be used.

In one embodiment, the polyetherimide comprises structural units of formula (5) wherein each R is independently p-phenylene or m-phenylene or a mixture comprising at least one of the foregoing; and T is group of the formula —O—Z—O— wherein the divalent bonds of the —O—Z—O— group are in the 3,3′ positions, and Z is 2,2-diphenylenepropane group (a bisphenol A group). Further, the polyetherimidesulfone comprises structural units of formula (6) wherein at least 50 mole % of the R groups are of formula (4) wherein Q is —SO₂— and the remaining R groups are independently p-phenylene or m-phenylene or a combination comprising at least one of the foregoing; and T is group of the formula —O—Z—O— wherein the divalent bonds of the —O—Z—O— group are in the 3,3′ positions, and Z is a 2,2-diphenylenepropane group.

The polyetherimide and polyetherimidesulfone can be used alone or in combination with each other and/or other of the disclosed polymeric materials in fabricating the polymeric components of the invention. In one embodiment, only the polyetherimide is used. In another embodiment, the weight ratio of polyetherimide: polyetherimidesulfone can be from 99:1 to 50:50.

The polyetherimides can have a weight average molecular weight (Mw) of 5,000 to 100,000 grams per mole (g/mole) as measured by gel permeation chromatography (GPC). In some embodiments the Mw can be 10,000 to 80,000. The molecular weights as used herein refer to the absolute weight averaged molecular weight (Mw).

The polyetherimides can have an intrinsic viscosity greater than or equal to 0.2 deciliters per gram (dl/g) as measured in m-cresol at 25° C. Within this range the intrinsic viscosity can be 0.35 to 1.0 dl/g, as measured in m-cresol at 25° C.

The polyetherimides can have a glass transition temperature of greater than 180° C., specifically of 200° C. to 500° C., as measured using differential scanning calorimetry (DSC) per ASTM test D3418. In some embodiments, the polyetherimide and, in particular, a polyetherimide has a glass transition temperature of 240 to 350° C.

The polyetherimides can have a melt index of 0.1 to 10 grams per minute (g/min), as measured by American Society for Testing Materials (ASTM) DI 238 at 340 to 370° C., using a 6.7 kilogram (kg) weight.

An alternative halo-displacement polymerization process for making polyetherimides, e.g., polyetherimides having structure (1) is a process referred to as the chloro-displacement process (X is Cl in formula (8)). The chloro-displacement process is illustrated as follows: 4-chloro phthalic anhydride and meta-phenylene diamine are reacted in the presence of a catalytic amount of sodium phenyl phosphinate catalyst to produce the bischlorophthalimide of meta-phenylene diamine (CAS No. 148935-94-8). The bischlorophthalimide is then subjected to polymerization by chloro-displacement reaction with the disodium salt of BPA in the presence of a catalyst in ortho-dichlorobenzene or anisole solvent. Alternatively, mixtures of 3-chloro- and 4-chlorophthalic anhydride may be employed to provide a mixture of isomeric bischlorophthalimides which may be polymerized by chloro-displacement with BPA disodium salt as described above.

Siloxane polyetherimides can include polysiloxane/polyetherimide block copolymers having a siloxane content of greater than 0 and less than 40 weight percent (wt %) based on the total weight of the block copolymer. The block copolymer comprises a siloxane block of Formula (11):

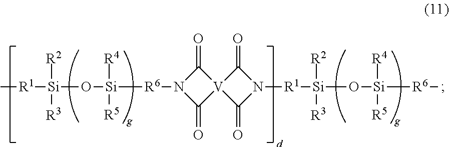

wherein R¹⁻⁶ are independently at each occurrence selected from the group consisting of substituted or unsubstituted, saturated, unsaturated, or aromatic monocyclic groups having 5 to 30 carbon atoms, substituted or unsubstituted, saturated, unsaturated, or aromatic polycyclic groups having 5 to 30 carbon atoms, substituted or unsubstituted alkyl groups having 1 to 30 carbon atoms and substituted or unsubstitutedalkenyl groups having 2 to 30 carbon atoms, V is a tetravalent linker selected from the group consisting of substituted or unsubstituted, saturated, unsaturated, or aromatic monocyclic and polycyclic groups having 5 to 50 carbon atoms, substituted or unsubstituted alkyl groups having 1 to 30 carbon atoms, substituted or unsubstitutedalkenyl groups having 2 to 30 carbon atoms and combinations comprising at least one of the foregoing linkers, g equals 1 to 30, and d is 2 to 20. Commercially available siloxane polyetherimides can be obtained from SABIC Innovative Plastics under the brand name SILTEM* (*Trademark of SABIC Innovative Plastics IP B.V.)

The polyetherimide resin can have a weight average molecular weight (Mw) within a range having a lower limit and/or an upper limit. The range can include or exclude the lower limit and/or the upper limit. The lower limit and/or upper limit can be selected from 5000, 6000, 7000, 8000, 9000, 10000, 11000, 12000, 13000, 14000, 15000, 16000, 17000, 18000, 19000, 20000, 21000, 22000, 23000, 24000, 25000, 26000, 27000, 28000, 29000, 30000, 31000, 32000, 33000, 34000, 35000, 36000, 37000, 38000, 39000, 40000, 41000, 42000, 43000, 44000, 45000, 46000, 47000, 48000, 49000, 50000, 51000, 52000, 53000, 54000, 55000, 56000, 57000, 58000, 59000, 60000, 61000, 62000, 63000, 64000, 65000, 66000, 67000, 68000, 69000, 70000, 71000, 72000, 73000, 74000, 75000, 76000, 77000, 78000, 79000, 80000, 81000, 82000, 83000, 84000, 85000, 86000, 87000, 88000, 89000, 90000, 91000, 92000, 93000, 94000, 95000, 96000, 97000, 98000, 99000, 100000, 101000, 102000, 103000, 104000, 105000, 106000, 107000, 108000, 109000, and 110000 daltons. For example, the polyetherimide resin can have a weight average molecular weight (Mw) from 5,000 to 100,000 daltons, from 5,000 to 80,000 daltons, or from 5,000 to 70,000 daltons. The primary alkyl amine modified polyetherimide will have lower molecular weight and higher melt flow than the starting, unmodified, polyetherimide.

In a further aspect, the polyetherimide has a structure represented by a formula:

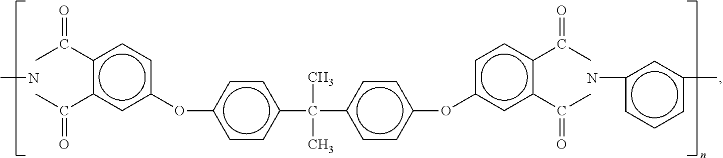

wherein the polyetherimide polymer has a molecular weight of at least 20,000, 30,000, 40,000 Daltons, 50,000 Daltons, 60,000 Daltons, 80,000 Daltons, or 100,000 Daltons.

In one aspect, the polyetherimide comprises

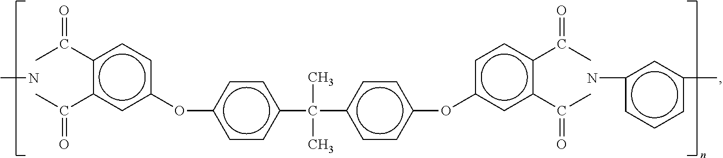

wherein n is greater than 1, for example greater than 10. In one aspect n is between 2-100, 2-75, 2-50 or 2-25, for example 10-100, 10-75, 10-50 or 10-25. In another example, n can be 38, 56 or 65.

The polyetherimide resin can be selected from the group consisting of a polyetherimide, for example as described in U.S. Pat. Nos. 3,875,116; 6,919,422 and 6,355,723 a silicone polyetherimide, for example as described in U.S. Pat. Nos. 4,690,997; 4,808,686 a polyetherimidesulfone resin, as described in U.S. Pat. No. 7,041,773 and combinations thereof, each of these patents are incorporated herein their entirety.

The polyetherimide resin can have a glass transition temperature within a range having a lower limit and/or an upper limit. The range can include or exclude the lower limit and/or the upper limit. The lower limit and/or upper limit can be selected from 100, 110, 120, 130, 140, 150, 160, 170, 180, 190, 200, 210, 220, 230, 240, 250, 260, 270, 280, 290, 300 and 310 degrees Celsius. For example, the polyetherimide resin can have a glass transition temperature (Tg) greater than about 200 degrees Celsius.

The polyetherimide resin can be substantially free (less than 100 ppm) of benzylic protons. The polyetherimide resin can be free of benzylic protons. The polyetherimide resin can have an amount of benzylic protons below 100 ppm. In one embodiment, the amount of benzylic protons ranges from more than 0 to below 100 ppm. In another embodiment, the amount of benzylic protons is not detectable.

The polyetherimide resin can be substantially free (less than 100 ppm) of halogen atoms. The polyetherimide resin can be free of halogen atoms. The polyetherimide resin can have an amount of halogen atoms below 100 ppm. In one embodiment, the amount of halogen atoms range from more than 0 to below 100 ppm. In another embodiment, the amount of halogen atoms is not detectable.

Suitable polyetherimides that can be used in the disclosed composites include, but are not limited to, ULTEM™. ULTEM™ is a polymer from the family of polyetherimides (PEI) sold by Saudi Basic Industries Corporation (SABIC). ULTEM™ can have elevated thermal resistance, high strength and stiffness, and broad chemical resistance. ULTEM™ as used herein refers to any or all ULTEM™ polymers included in the family unless otherwise specified. In a further aspect, the ULTEM™ is ULTEM™ 1000. In one aspect, a polyetherimide can comprise any polycarbonate material or mixture of materials, for example, as recited in U.S. Pat. No. 4,548,997; U.S. Pat. No. 4,629,759; U.S. Pat. No. 4,816,527; U.S. Pat. No. 6,310,145; and U.S. Pat. No. 7,230,066, all of which are hereby incorporated in its entirety for the specific purpose of disclosing various polyetherimide compositions and methods.

(2) Polycarbonate

As described, the polymer substrate can comprise a polycarbonate. The terms “polycarbonate” or “polycarbonates” as used herein includes copolycarbonates, homopolycarbonates and (co)polyester carbonates.

In one aspect, the polycarbonate can comprises aromatic carbonate chain units and includes compositions having structural units of the formula:

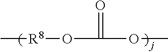

wherein at least about 60 percent of the total number of R⁸ groups are aromatic organic radicals and the balance thereof are aliphatic, alicyclic, or aromatic radicals, wherein j is at least 2.

In one aspect, R⁸ can be an aromatic organic radical and, such as a radical of the formula:

-A¹-Y¹-A²-

wherein each of A¹ and A² is a monocyclic, divalent aryl radical and Y′ is a bridging radical having one or two atoms which separate A¹ from A². For example, one atom separates A¹ from A². Illustrative non-limiting examples of radicals of this type are —O—, —S—, —S(O)—, —S(O₂)—, —C(O)—, methylene, cyclohexyl-methylene, 2-[2.2.1]-bicycloheptylidene, ethylidene, isopropylidene, neopentylidene, cyclohexylidene, cyclopentade-cylidene, cyclododecylidene, and adamantylidene. The bridging radical Y¹ can be a hydrocarbon group or a saturated hydrocarbon group such as methylene, cyclohexylidene or isopropylidene.

Polycarbonate resins can be produced by the reaction of the carbonate precursor with dihydroxy compounds. Typically, an aqueous base such as (e.g., sodium hydroxide, potassium hydroxide, calcium hydroxide, and the like,) is mixed with an organic, water immiscible solvent such as benzene, toluene, carbon disulfide, or dichloromethane, which contains the dihydroxy compound. A phase transfer resin is generally used to facilitate the reaction. Molecular weight regulators may be added to the reactant mixture. These molecular weight regulators may be added singly or as a combination. Branching resins, described forthwith may also be added singly or in admixture. Another process for producing aromatic polycarbonate resins is the trans-esterification process, which involves the trans-esterification of an aromatic dihydroxy compound and a diester carbonate. This process is known as the melt polymerization process. The process of producing the aromatic polycarbonate resins is not critical.

As used herein, the term “dihydroxy compound” includes, for example, bisphenol compounds having general formula (12) as follows:

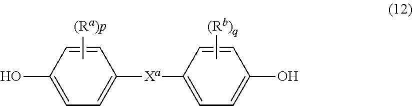

wherein R^{a} and R^{b} each represent a halogen atom, for example chlorine or bromine, or a monovalent hydrocarbon group, the monovalent hydrocarbon group can have from 1 to 10 carbon atoms, and can be the same or different; p and q are each independently integers from 0 to 4; Preferably, X^{a} represents one of the groups of formula:

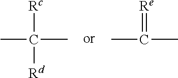

wherein R^{c} and R^{d} each independently represent a hydrogen atom or a monovalent linear or cyclic hydrocarbon group and R^{e} is a divalent hydrocarbon group.

Non-limiting examples of suitable dihydroxy compounds include the dihydroxy-substituted aromatic hydrocarbons disclosed by name or formula (generic or specific) in U.S. Pat. No. 4,217,438, which is incorporated herein by reference. A nonexclusive list of specific examples of the types of bisphenol compounds includes Some illustrative, non-limiting examples of suitable dihydroxy compounds include the following: resorcinol, 4-bromoresorcinol, hydroquinone, 4,41-dihydroxybiphenyl, 1,6-dihydroxynaphthalene, 2,6-dihydroxynaphthalene, bis(4-hydroxyphenyl)methane, bis(4-hydroxyphenyl) diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl) propane, 1,1-bis(hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantine, (alpha,alpha1-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl) propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene, 4,4′ dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxy-yphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, and the like, as well as combinations comprising at least one of the foregoing dihydroxy compounds.

Specific examples of the types of bisphenol compounds that may be represented by formula (3) include 1,1-bis(4-hydroxyphenyl)methane, 1,1-bis(4-hydroxyphenyl)ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl)ₙ-butane, 2,2-bis(4-hydroxy-1-methylphenyl)propane, and 1,1-bis(4-hydroxy-t-butylphenyl)propane. Combinations comprising at least one of the foregoing dihydroxy compounds may also be used.

Branched polycarbonates are also useful, as well as blends of a linear polycarbonate and a branched polycarbonate. The branched polycarbonates may be prepared by adding a branching agent during polymerization. These branching agents include polyfunctional organic compounds containing at least three functional groups selected from hydroxyl, carboxyl, carboxylic anhydride, haloformyl, and mixtures of the foregoing functional groups. Specific examples include trimellitic acid, trimellitic anhydride, trimellitic trichloride, tris-p-hydroxy phenyl ethane, isatin-bis-phenol, tris-phenol TC (1,3,5-tris((p-hydroxyphenyl)isopropyl)benzene), tris-phenol PA (4(4(1,1-bis(p-hydroxyphenyl)-ethyl)alpha,alphadimethyl benzyl)phenol), 4-chloroformyl phthalic anhydride, trimesic acid, and benzophenone tetracarboxylic acid. The branching agents may be added at a level of about 0.05 wt % to about 2.0 wt %. All types of polycarbonate end groups are contemplated as being useful in the polycarbonate composition, provided that such end groups do not significantly affect desired properties of the thermoplastic compositions.

Suitable polycarbonates can be manufactured by processes such as interfacial polymerization and melt polymerization. Although the reaction conditions for interfacial polymerization may vary, an exemplary process generally involves dissolving or dispersing a dihydric phenol reactant in aqueous caustic soda or potash, adding the resulting mixture to a suitable water-immiscible solvent medium, and contacting the reactants with a carbonate precursor in the presence of a suitable catalyst such as triethylamine or a phase transfer catalyst, under controlled pH conditions, e.g., about 8 to about 10. The most commonly used water immiscible solvents include methylene chloride, 1,2-dichloroethane, chlorobenzene, toluene, and the like. Suitable carbonate precur sors include, for example, a carbonyl halide such as carbonyl bromide or carbonyl chloride, or a haloformate such as a bishaloformate of a dihydric phenol (e.g., the bischloroformates of bisphenol A, hydroquinone, or the like) or a glycol (e.g., the bishaloformate of ethylene glycol, neopentyl glycol, polyethylene glycol, or the like). Combinations comprising at least one of the foregoing types of carbonate precursors may also be used.

Rather than utilizing the dicarboxylic acid per se, it is possible, and sometimes even desired, to employ the reactive derivatives of the acid, such as the corresponding acid halides, in particular the acid dichlorides and the acid dibromides. Thus, for example, instead of using isophthalic acid, terephthalic acid, or mixtures thereof, it is possible to employ isophthaloyl dichloride, terephthaloyl dichloride, and mixtures thereof.

Non-limiting examples of suitable phase transfer resins include, but are not limited to, tertiary amines such as triethylamine, quaternary ammonium compounds, and quaternary phosphonium compounds.

Among the phase transfer catalysts that may be used are catalysts of the formula (R⁹)₄Q+X, wherein each R⁹ is the same or different, and is a C₁₋₁₀ alkyl group; Q is a nitrogen or phosphorus atom; and X is a halogen atom or a C₁₋₈ alkoxy group or C₆₋₁₈ aryloxy group. Suitable phase transfer catalysts include, for example, [CH₃(CH₂)₃]₄NX, [CH₃(CH₂)₃]₄PX, [CH₃(CH₂)₅]₄NX, [CH₃(CH₂)₆]₄NX, [CH₃(CH₂)₄]₄NX, CH₃[CH₃(CH₂)]₃NX, and CH₃[CH₃(CH₂)₂NX, wherein X is Cl—, Br—, a C₁₋₈ alkoxy group or a C₆₋₁₈ aryloxy group. An effective amount of a phase transfer catalyst may be about 0.1 to about 10 wt % based on the weight of bisphenol in the phosgenation mixture. In another embodiment an effective amount of phase transfer catalyst may be about 0.5 to about 2 wt % based on the weight of bisphenol in the phosgenation mixture.

Alternatively, melt processes may be used to make the polycarbonates. Generally, in the melt polymerization process, polycarbonates may be prepared by co-reacting, in a molten state, the dihydroxy reactant(s) and a diaryl carbonate ester, such as diphenyl carbonate, in the presence of a transesterification catalyst in a Banbury® mixer, twin screw extruder, or the like to form a uniform dispersion. Volatile monohydric phenol is removed from the molten reactants by distillation and the polymer is isolated as a molten residue.

Typical carbonate precursors include the carbonyl halides, for example carbonyl chloride (phosgene), and carbonyl bromide; the bis-haloformates, for example the bis-haloformates of dihydric phenols such as bisphenol A, hydroquinone, and the like, and the bis-haloformates of glycols such as ethylene glycol and neopentyl glycol; and the diaryl carbonates, such as diphenyl carbonate, di(tolyl) carbonate, and di(naphthyl) carbonate.

In one aspect, bisphenols can be used in the manufacture of polycarbonates containing phthalimidine carbonate units of formula (12a)

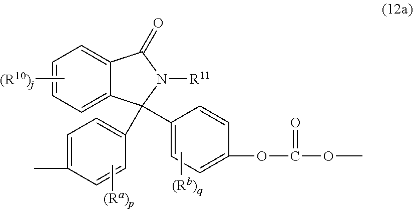

wherein R^{a}, R^{b}, p, and q are as in formula (12), R¹⁰ is each independently a C₁₋₆ alkyl group, j is 0 to 4, and R¹¹ is a C₁₋₆ alkyl, phenyl, or phenyl substituted with up to five C₁₋₆ alkyl groups. In particular, the phthalimidine carbonate units are of formula (12b)

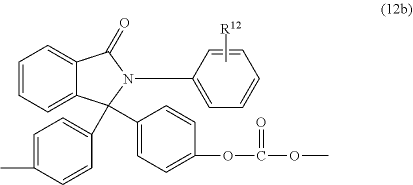

wherein R¹² is hydrogen or a C₁₋₆ alkyl. In an embodiment, R¹² is hydrogen. Carbonate units (12a) wherein R¹² is hydrogen can be derived from 2-phenyl-3,3′-bis(4-hydroxy phenyl)phthalimidine (also known as N-phenyl phenolphthalein bisphenol, or “PPPBP”) (also known as 3,3-bis(4-hydroxyphenyl)-2-phenylisoindolin-1-one).

Other bisphenol carbonate repeating units of this type are the instant carbonate units of formula (12c) and (12d)

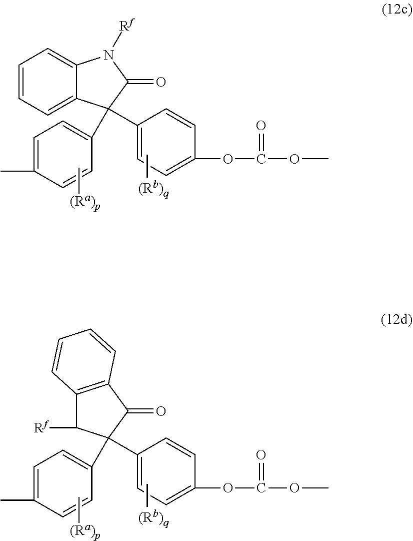

wherein R^{a} and R^{b} are each independently C₁₋₁₂ alkyl, p and q are each independently 0 to 4, and R^{f} is C₁₋₁₂ alkyl, phenyl, optionally substituted with 1to 5 to C₁₋₁₀ alkyl, or benzyl optionally substituted with 1 to 5 C₁₋₁₀ alkyl. In an embodiment, R^{a} and R^{b} are each methyl, p and q are each independently 0 or 1, and R^{f} is C₁₋₄ alkyl or phenyl.

Examples of bisphenol carbonate units derived from bisphenols of formula (12) wherein X^{a} is a substituted or unsubstituted C₃₋₁₈ cycloalkylidene include the cyclohexylidene-bridged, alkyl-substituted bisphenol of formula (12e)

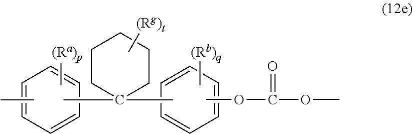

wherein R^{a} and R^{b} are each independently C₁₋₁₂ alkyl, R^{g} is C₁₋₁₂ alkyl, p and q are each independently 0 to 4, and t is 0 to 10. In a specific embodiment, at least one of each of R^{a} and R^{b} are disposed meta to the cyclohexylidene bridging group. In an embodiment, R^{a} and R^{b} are each independently C₁₋₄ alkyl, R^{g} is C₁₋₄ alkyl, p and q are each 0 or 1, and t is 0 to 5. In another specific embodiment, R^{a}, R^{b}, and R^{g} are each methyl, r and s are each 0 or 1, and t is 0 or 3, specifically 0.

Examples of other bisphenol carbonate units derived from bisphenol wherein X^{a} is a substituted or unsubstituted C₃₋₁₈ cycloalkylidene include adamantyl units (12f) and units (12g)

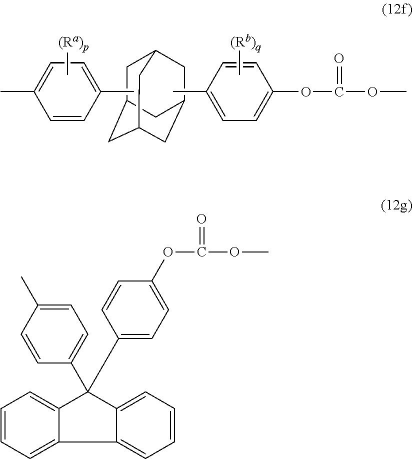

wherein R^{a} and R^{b} are each independently C₁₋₁₂ alkyl, and p and q are each independently 1 to 4. In a specific embodiment, at least one of each of R^{a} and R^{b} are disposed meta to the cycloalkylidene bridging group. In an embodiment, R^{a} and R^{b} are each independently C₁₋₃ alkyl, and p and q are each 0 or 1. In another specific embodiment, R^{a}, R^{b} are each methyl, p and q are each 0 or 1. Carbonates containing units (12a) to (12g) are useful for making polycarbonates with high glass transition temperatures (Tg) and high heat distortion temperatures.

“Polycarbonates” and “polycarbonate polymers” as used herein further includes blends of polycarbonates with other copolymers comprising carbonate chain units. An exemplary copolymer is a polyester carbonate, also known as a copolyester-polycarbonate. Such copolymers further contain, in addition to recurring carbonate chain units, repeating units of formula (13)

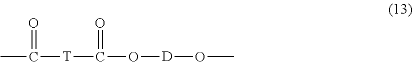

wherein D is a divalent radical derived from a dihydroxy compound, and may be, for example, a C₂₋₁₀ alkylene radical, a C₆₋₂₀ alicyclic radical, a C₆₋₂₀ aromatic radical or a polyoxyalkylene radical in which the alkylene groups contain 2 to about 6 carbon atoms, specifically 2, 3, or 4 carbon atoms; and T is a divalent radical derived from a dicarboxylic acid, and may be, for example, a C₂₋₁₀ alkylene radical, a C₆₋₂₀ alicyclic radical, a C₆₋₂₀ alkyl aromatic radical, or a C₆₋₂₀ aromatic radical.

In one embodiment, D is a C₂₋₆ alkylene radical. In another embodiment, D is derived from an aromatic dihydroxy compound of formula (14):

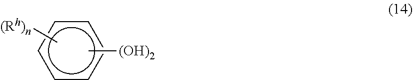

wherein each R^{h} is independently a halogen atom, a C₁₋₁₀ hydrocarbon group, or a C₁₋₁₀ halogen substituted hydrocarbon group, and n is 0 to 4. The halogen is usually bromine. Examples of compounds that may be represented by the formula (14) include resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propylhydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, or the like; or combinations comprising at least one of the foregoing compounds.

Examples of aromatic dicarboxylic acids that may be used to prepare the polyesters include isophthalic or terephthalic acid, 1,2-di(p-carboxyphenyl)ethane, 4,4′-dicarboxydiphenyl ether, 4,4′-bisbenzoic acid, and mixtures comprising at least one of the foregoing acids. Acids containing fused rings can also be present, such as in 1,4-, 1,5-, or 2,6-naphthalenedicarboxylic acids. Specific dicarboxylic acids are terephthalic acid, isophthalic acid, naphthalene dicarboxylic acid, cyclohexane dicarboxylic acid, or mixtures thereof. A specific dicarboxylic acid comprises a mixture of isophthalic acid and terephthalic acid wherein the weight ratio of terephthalic acid to isophthalic acid is about 10:1 to about 0.2:9.8. In another specific embodiment, D is a C₂₋₆ alkylene radical and T is p-phenylene, m-phenylene, naphthalene, a divalent cycloaliphatic radical, or a mixture thereof. This class of polyester includes the poly(alkylene terephthalates).

In other embodiments, poly(alkylene terephthalates) may be used. Specific examples of suitable poly(alkylene terephthalates) are poly(ethylene terephthalate) (PET), poly(1,4-butylene terephthalate) (PBT), poly(ethylene naphthanoate) (PEN), poly(butylene naphthanoate), (PBN), (polypropylene terephthalate) (PPT), polycyclohexanedimethanol terephthalate (PCT), and combinations comprising at least one of the foregoing polyesters. Also contemplated are the above polyesters with a minor amount, e.g., from about 0.5 to about 10 percent by weight, of units derived from an aliphatic diacid and/or an aliphatic polyol to make copolyesters.

Copolymers comprising alkylene terephthalate repeating ester units with other ester groups may also be useful. Useful ester units may include different alkylene terephthalate units, which can be present in the polymer chain as individual units, or as blocks of poly(alkylene terephthalates). Specific examples of such copolymers include poly (cyclohexanedimethylene terephthalate)-co-poly(ethylene terephthalate), abbreviated as PETG where the polymer comprises greater than or equal to 50 mol % of poly(ethylene terephthalate), and abbreviated as PCTG where the polymer comprises greater than 50 mol % of poly(1,4-cyclohexanedimethylene terephthalate).

Poly(cycloalkylene diester)s may also include poly(alkylene cyclohexanedicarboxylate)s. Of these, a specific example is poly(1,4-cyclohexanedimethanol-1,4-cyclohexanedicarboxylate) (PCCD), having recurring units of formula (15):

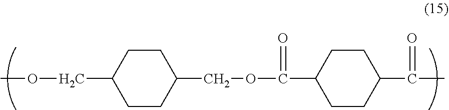

wherein, as described using formula (13), D is a 1,4-cyclohexanedimethylene group derived from 1,4-cyclohexanedimethanol, and T is a cyclohexane ring derived from cyclohexanedicarboxylate or a chemical equivalent thereof, and may comprise the cis-isomer, the trans-isomer, or a combination comprising at least one of the foregoing isomers.

Typical branching resins such as α,α,α′,α′-tetrakis(3-methyl-4-hydroxyphenyl)-p-xylene, α,α,α′,α′-tetrakis (2-methyl-4-hydroxyphenyl)-p-xylene, α,α,α′,α′-tetrakis(2,5 dimethyl-4-hydroxyphenyl)-p-xylene, α,α,α′,α′-tetrakis(2,6 dimethyl-4-hydroxyphenyl)-p-xylene, α,α,α′,α′-tetrakis(4-hydroxyphenyl)-p-xylene, trimellitic acid, trimellitic anhydride, trimellitic trichloride, tris-p-hydroxy phenyl ethane, isatin-bis-phenol, tris-phenol TC (1,3,5-tris((p-hydroxyphenyl)isopropyl)benzene), tris-phenol PA (4-(4-(1,1-bis(p-hydroxyphenyl)-ethyl)alpha, alpha-dimethylbenzyl)phenol), 4-chloroformyl phthalic anhydride, trimesic acid, benzophe-none tetracarboxylic acid and the like, can also be added to the reaction mixture. Blends of linear polycarbonate and branched polycarbonate resins can be utilized herein. The branching agent may be added at a level of about 0.05 to about 2.0 weight percent (wt %).

Molecular weight regulators or chain stoppers are optional and are added to the mixture in order to arrest the progress of the polymerization. Typical molecular weight regulators such as phenol, chroman-1, p-t-butylphenol, p-bromophenol, para-cumyl-phenol, and the like may be added either singly or in admixture and are typically added in an amount of about 1 to about 10 mol % excess with respect to the BPA. The molecular weight of the polycarbonate is generally greater than or equal to about 5000, preferably greater than or equal to about 10,000, more preferably greater than or equal to about 15,000 g/mole. In general it is desirable to have the polycarbonate resin less than or equal to about 100,000, preferably less than or equal to about 50,000, more preferably less than or equal to about 30,000 g/mole as calculated from the viscosity of a methylene chloride solution at 25° C. In one aspect, the polycarbonate can have a Mn of about 15,000 to about 30,000. In another aspect, the polycarbonate can have a Mn of about 20,000 to about 25,000. In another aspect, the polycarbonate can have a Mn of about 21,000. In another aspect, the polycarbonate can have a Mn of about 24,000.

In one aspect, the polycarbonate can comprise two or more polycarbonates. For example, the polycarbonate can comprise two polycarbonates. The two polycarbonates can be present in about equal amounts.

In one aspect, the polycarbonates can be a part of a co-polymer, wherein at least one part of the co-polymer is not a polycarbonate.

2. Composite Additives

In one aspect, the polymer substrate can comprise a polymer described herein and a composite additive.

In one aspect, the composite additive can be an inorganic material. For example, the composite additive can comprise one or more of the following: SiO₂, Si₃N₄, Al₂O₃, BN, Ta₂O₅, Nb₂O₅, TiO₂, SrTiO₃, BaTiO₃, ZrO₂, HfO₂, or a combination thereof. Thus, for example, the composite additive can comprise BaTiO₃.

In another aspect, the composite additive can be present in 5%, 10%, 15%, 20%, 25%, 30%, 35%, 40%, 45%, 50%, 55%, 60%, 65%, or 70% by weight in the polymer substrate. For example, the composite additive can be present in 20%, 25%, 30%, 35%, 40%, 45%, or 50% by weight in the polymer substrate. In another example, the composite additive can be present in 25%, 30%, or 35% by weight in the polymer substrate. In yet another example, the composite additive can be present in about 30% by weight in the polymer substrate.

3. Inorganic Material

The inorganic material of the present invention can comprise any inorganic material capable of improving the dielectric strength of a polymer material. In one aspect, the inorganic material should be chemically compatible with the polymer substrate. In another aspect, the inorganic material should be capable of adhering and/or forming a thin film on a surface of the polymer substrate without spalling, flaking, and/or delaminating during handling or use.

In one aspect, the inorganic material can comprise an oxide, such as, for example, silica, alumina, tantalum oxide, for example, tantalum pentoxide, niobium oxide, for example, niobium pentoxide, titanium oxide, for example, titania, strontium titanate, barium titanate, zirconium oxide, hafnium oxide, and/or a nitride, such as, for example, silicon nitride, boron nitride, or a combination thereof. In another aspect, the inorganic material comprises one or more of the following: SiO₂, Si₃N₄, Al₂O₃, BN, Ta₂O₅, Nb₂O₅, TiO₂, SrTiO₃, BaTiO₃, ZrO₂, HfO₂, or a combination thereof. In a specific aspect, the inorganic material comprises silica. In another aspect, the inorganic material does not comprise silica. In yet another aspect, the inorganic material does not comprise silica or alumina.

In one aspect, the inorganic material comprises silicon nitride. In one aspect, the inorganic material comprises alumina. In one aspect, the inorganic material comprises boron nitride. In one aspect, the inorganic material comprises tantalum pentoxide. In one aspect, the inorganic material comprises niobium pentoxide. In one aspect, the inorganic material comprises titania. In one aspect, the inorganic material comprises strontium titanate. In one aspect, the inorganic material comprises barium titanate. In one aspect, the inorganic material comprises zirconia. In one aspect, the inorganic material comprises hafnium oxide. In other aspects, the inorganic material can specifically exclude any one or more of the individual inorganic materials recited herein. In one aspect, the inorganic material does not comprise silica. In another aspect, the inorganic material does not comprise alumina.

In other aspects, the inorganic material can comprise other dielectric materials not specifically recited herein, for example, a compound other than an oxide and/or nitride. In another aspect, the inorganic material can comprise a mixture of any two or more individual inorganic materials. If two or more individual inorganic materials are utilized, any two or more inorganic materials can be deposited simultaneously or sequentially.

The inorganic material can comprise a single layer or multiple individual layers of the same or varying composition. In one aspect, the inorganic material comprises a single layer. In another aspect, the inorganic material comprises multiple layers on the same side of the polymer substrate and/or on opposing sides of the polymer substrate. In one aspect, the inorganic material is a dielectric material or has dielectric properties. In an exemplary aspect, a single layer of an inorganic material or mixture of inorganic materials is disposed on one surface of the polymer substrate.

In one aspect, the inorganic material has a low dielectric constant. In another aspect, the inorganic material has a high dielectric constant.

In various aspects, the inorganic material can be deposited on one or both surfaces of the polymer substrate. In another aspect, the inorganic material can be deposited on a portion of or all of one or both surfaces of the polymer substrate. In one aspect, the inorganic material is present on one side of the polymer substrate. In another aspect, the inorganic material is present on opposing sides of the polymer substrate. For example, an inorganic material with a high dielectric constant can be present on one side of the polymer substrate. In another example, an inorganic material with a high dielectric constant can be present on opposing sides of the polymer substrate. Thus, for example, TiO₂, Ta₂O₅, and/or SrTiO₃ can be present on opposing sides of the polymer substrate. In yet another example, an inorganic material with a low dielectric constant can be present on one side of the polymer substrate. In another example, an inorganic material with a low dielectric constant can be present on opposing sides of the polymer substrate. Thus, for example, SiO₂ can be present on opposing sides of the polymer substrate. In yet another aspect, an inorganic material with a high dielectric constant can be present on one side of the polymer substrate and an inorganic material with a low dielectric constant can be present on the opposing side of the polymer substrate. Thus, for example, TiO₂, Ta₂O₅, and/or SrTiO₃ can be present on one side of the polymer substrate and SiO₂ can be present on the opposing side of the polymer substrate.

In yet another example, an inorganic material with a low dielectric constant and an inorganic material with a high dielectric constant can be present on one side of the polymer substrate. Thus, for example, TiO₂, Ta₂O₅, and/or SrTiO₃ and SiO₂ can be present on one side of the polymer substrate. In yet another example, an inorganic material with a low dielectric constant and an inorganic material with a high dielectric constant can both be present on opposing sides of the polymer substrate. Thus, for example, TiO₂, Ta₂O₅, and/or SrTiO₃ and SiO₂ can be present on opposing sides of the polymer substrate. In one aspect, the inorganic material with a low dielectric constant can be in contact with the polymer substrate. Thus, for example, SiO₂ can be in contact with the polymer substrate. In another aspect, the inorganic material with a high dielectric constant can be in contact with the polymer substrate. Thus, for example, TiO₂, Ta₂O₅, and/or SrTiO₃ can be in contact with the polymer substrate. In yet another example, the inorganic material with a low dielectric constant can be in contact with the polymer substrate and the inorganic material with a high dielectric constant is not in contact with the polymer substrate. In another example, the inorganic material with a low dielectric constant can be in contact with the polymer substrate and the inorganic material with a high dielectric constant is in contact with the inorganic material with a low dielectric constant. In another example, the inorganic material with a high dielectric constant can be in contact with the polymer substrate and the inorganic material with a low dielectric constant is not in contact with the polymer substrate. In yet another example, the inorganic material with a high dielectric constant can be in contact with the polymer substrate and the inorganic material with a low dielectric constant is in contact with the inorganic material with a high dielectric constant.

In another aspect, an inorganic material with a high dielectric constant can be present on one side of the polymer substrate and an inorganic material with a low dielectric constant and an inorganic material with a high dielectric constant can both be present on the opposing side of the polymer substrate. In another aspect, an inorganic material with a low dielectric constant can be present on one side of the polymer substrate and an inorganic material with a low dielectric constant and an inorganic material with a high dielectric constant can both be present on the opposing side of the polymer substrate.

The inorganic material can be deposited by any suitable method. In one aspect, the inorganic material can be deposited using a vacuum technique. In another aspect, the inorganic material can be deposited using a sputtering technique. In another aspect, the inorganic material can be deposited using a vapor deposition technique, such as, for example, chemical vapor deposition (CVD), plasma enhanced chemical vapor deposition (PECVD), or atomic layer deposition (ALD). In another aspect, one or more conventional deposition techniques can be modified to facilitate the deposition of a selected inorganic material on a polymer substrate.

In one aspect, the inorganic material is deposited onto the polymer substrate by sputtering techniques. In one aspect, the inorganic material is deposited onto the polymer substrate by reactive sputtering. In another aspect, the inorganic material is deposited onto the polymer substrate by magnetron sputtering. In yet another aspect, the inorganic material is deposited onto the polymer substrate by radio frequency (RF) sputtering. RF sputtering can include reactive sputtering and/or magnetron sputtering.

In one aspect, the sputtering techniques comprise using O₂. In one aspect, sputtering techniques comprise using O₂ flow (sccm) in an amount that is suitable for the polymer substrate. The O₂ both can assist in the formation of the inorganic oxide material but the same time be corrosive towards the polymer substrate. Thus, the amount of O₂ flow can be adjusted for each polymer substrate. In one aspect, sputtering techniques comprise using at least 3%, 5%, 7%, 9%, 11%, 13%, 14%, 16%, 18%, 20%, 22%, or 24% O₂. In one aspect, sputtering techniques comprise using less than 3%, 5%, 7%, 9%, 11%, 13%, 14%, 16%, 18%, 20%, 22%, or 24% O₂. In one aspect, sputtering techniques comprise using about 3%, 5%, 7%, 9%, 11%, 13%, 14%, 16%, 18%, 20%, 22%, or 24% O₂. For example, in one aspect the sputtering technique uses about 18% O₂ (sccm).

The thickness of the inorganic material can vary based on, for example, the inorganic material, the polymer substrate, and/or the desired dielectric properties of the resulting coated polymer film. In one aspect, the inorganic coating can range from about 1 nm to about 1,000 nm, for example, about 1, 2, 3, 4, 5, 6, 7, 8, 9, 10, 15, 20, 25, 30, 35, 40, 45, 50, 55, 60, 65, 70, 75, 80, 85, 90, 100, 150, 200, 250, 300, 350, 400, 450, or 500 nm. In another aspect, the inorganic material can be deposited to a thickness of from about 10 nm to about 500 nm, for example, about 10, 15, 20, 25, 30, 35, 40, 45, 50, 55, 60, 65, 70, 75, 80, 85, 90, 95, 100, 200, 300, 400, or 500 nm; from about 20 nm to about 100 nm, for example, about 20, 25, 30, 35, 40, 45, 50, 55, 60, 65, 70, 75, 80, 85, 90, 95, or 100 nm; or from 20 nm to about 40 nm, for example, about 20, 22, 24, 26, 28, 30, 32, 34, 36, 38, or 40 nm. In another example, the inorganic material can be deposited to a thickness of from about 20 nm to about 200 nm. In another example, the inorganic material can be deposited to a thickness of from about 50 nm to about 150 nm. In another example, the inorganic material can be deposited to a thickness of from about 80 nm to about 120 nm.

In one aspect, an inorganic coating with a low dielectric constant can range from about 1 nm to about 1,000 nm, for example, about 1, 2, 3, 4, 5, 6, 7, 8, 9, 10, 15, 20, 25, 30, 35, 40, 45, 50, 55, 60, 65, 70, 75, 80, 85, 90, 100, 150, 200, 250, 300, 350, 400, 450, or 500 nm. In another aspect, the inorganic material with a low dielectric constant can be deposited to a thickness of from about 10 nm to about 500 nm, for example, about 10, 15, 20, 25, 30, 35, 40, 45, 50, 55, 60, 65, 70, 75, 80, 85, 90, 95, 100, 200, 300, 400, or 500 nm; from about 20 nm to about 100 nm, for example, about 20, 25, 30, 35, 40, 45, 50, 55, 60, 65, 70, 75, 80, 85, 90, 95, or 100 nm; or from 20 nm to about 40 nm, for example, about 20, 22, 24, 26, 28, 30, 32, 34, 36, 38, or 40 nm. In one example, the inorganic material with a low dielectric constant can be deposited to a thickness of about 20 nm to 200 nm. In one example, the inorganic material with a low dielectric constant can be deposited to a thickness of about 50 nm to 150 nm. In one example, the inorganic material with a low dielectric constant can be deposited to a thickness of about 80 nm to 120 nm. In one example, the inorganic material with a low dielectric constant can be deposited to a thickness of about 50 nm or 100 nm.

In one aspect, an inorganic coating with a high dielectric constant can range from about 1 nm to about 1,000 nm, for example, about 1, 2, 3, 4, 5, 6, 7, 8, 9, 10, 15, 20, 25, 30, 35, 40, 45, 50, 55, 60, 65, 70, 75, 80, 85, 90, 100, 150, 200, 250, 300, 350, 400, 450, or 500 nm. In another aspect, the inorganic material with a high dielectric constant can be deposited to a thickness of from about 10 nm to about 500 nm, for example, about 10, 15, 20, 25, 30, 35, 40, 45, 50, 55, 60, 65, 70, 75, 80, 85, 90, 95, 100, 200, 300, 400, or 500 nm; from about 20 nm to about 100 nm, for example, about 20, 25, 30, 35, 40, 45, 50, 55, 60, 65, 70, 75, 80, 85, 90, 95, or 100 nm; or from 20 nm to about 40 nm, for example, about 20, 22, 24, 26, 28, 30, 32, 34, 36, 38, or 40 nm. In one example, the inorganic material with a high dielectric constant can be deposited to a thickness of about 20 nm to about 200 nm. In one example, the inorganic material with a high dielectric constant can be deposited to a thickness of about 50 nm to about 150 nm. In one example, the inorganic material with a high dielectric constant can be deposited to a thickness of about 80 nm to about 120 nm. In one example, the inorganic material with a high dielectric constant can be deposited to a thickness of about 50 nm or about 100 nm.

In another aspect, other materials, such as dielectric or insulating organic materials can be deposited on the polymer substrate in addition to or in lieu of an inorganic material as described herein. In one aspect, an epoxy can be applied to one or both sides of a coated or uncoated polymer film.

4. Coated Polymer Substrate or Coated Polymer Composite Film

The coated polymer film (i.e., polymer substrate having a thin film of inorganic material deposited thereon) can have a substantially larger breakdown voltage than a comparable uncoated polymer film. In various aspects, a coated polymer film can have an breakdown voltage at least about 10%, 15%, 20%, 25%, 30%, 35%, 40%, 45%, or 50% higher than a comparable uncoated polymer film.

In one aspect, the coated polymer film is suitable for use as a dielectric material in an electronic component such as a capacitor. In another aspect, the coated polymer film and/or methods to coat a polymer film can provide improved performance without adding significant manufacturing or material costs, and without significant addition of weight to a resulting electronic component such as a capacitor.

In one aspect, the present invention does not comprise a layer of a silicon oxide (i.e., SiOₓ) material in contact with a layer of a silicon nitride (SiNₓ) material. In another aspect, the present invention does not comprise an integrated circuit. In yet another aspect, the present invention does not comprise an integrated circuit in direct contact with an inorganic material, such as, for example, a silica material. In still another aspect, the present invention does not comprise a semiconductor, although it should be understood that the inventive coated polymer film can be a part of an electrical component (e.g., a capacitor) that itself is part of a device comprising a semiconductor. In one aspect, the present invention does not comprise a semiconductor in direct contact with polymer substrate and/or an inorganic material.

The disclosed compositions and methods include at least the following aspects.

Aspect 1: A coated polymer composition, comprising a polymer substrate and an inorganic material present on at least one surface thereof, wherein the coated polymer composition has an improved dielectric strength as compared to an uncoated polymer substrate of the same composition, wherein the inorganic material has a thickness of about 20 nm to about 200 nm if the inorganic material present on the at least one surface does not comprise an inorganic material with a high dielectric constant. In one aspect of aspect 1, the inorganic material comprises an inorganic material with a high dielectric constant.

Aspect 2: The coated polymer composition of aspect 1, wherein the polymer substrate comprises polymethylmethacrylate, polyvinyl chloride, nylon, polyethylene terephthalate, polyimide, polyetherimide, polytetrafluoroethylene, polyethylene, ultra-high-molecular-weight polyethylene, polypropylene, polycarbonate, polystyrene, polysulfone, polyamides, aromatic polyamids, polyphenylene sulfide, polybutylene terephthalate, polyphenylene oxide, acrylonitrile butadiene styrene, polyetgerketone, polyetheretherketone, polyoxymethylene plastic, or a combination thereof.

Aspect 3: The coated polymer composition of aspects 1 or 2, wherein the polymer substrate comprises polyetherimide.

Aspect 4: The coated polymer composition of aspect 4, wherein the polyetherimide has the structure represented by a formula:

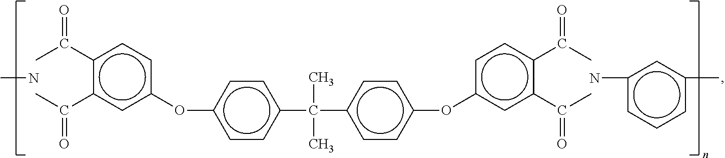

wherein the polyetherimide polymer has a molecular weight of at least 20,000 Daltons.

Aspect 5: The coated polymer composition of aspects 1 or 2, wherein the polymer substrate comprises a polycarbonate.

Aspect 6: The coated polymer composition of any of aspects 1, 2 or 5, wherein the polycarbonate comprises the formula:

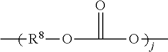

wherein at least about 60 percent of the total number of R⁸ groups are aromatic organic radicals and the balance thereof are aliphatic, alicyclic, or aromatic radicals, wherein j is at least 2.

Aspect 7: The coated polymer composition of any of aspects 1-6, wherein the polymer substrate does not comprise a cyano functionalized polymer.

Aspect 8: The coated polymer composition of any of aspects 1-7, wherein the polymer substrate does not comprise a polyetherimide derived from a cyano modified polyetherimide.

Aspect 9: The coated polymer composition of any of aspects 1-8, wherein the inorganic material is present on opposing sides of the polymer substrate.

Aspect 10: The coated polymer composition of any of aspects 1-9, wherein the inorganic material comprises an inorganic material with a low dielectric constant.

Aspect 11: The coated polymer composition of any of aspects 1-10, wherein the inorganic material comprises an inorganic material with a high dielectric constant.

Aspect 12: The coated polymer composition of any of aspects 1-11, wherein the inorganic material present on both opposing sides comprises an inorganic material with a low dielectric constant.

Aspect 13: The coated polymer composition of any of aspects 1-12, wherein the inorganic material comprises an inorganic material with a high dielectric constant and an inorganic material with a low dielectric constant.

Aspect 14: The coated polymer composition of any of aspects 1-13, wherein the inorganic material comprises SiO₂, Si₃N₄, Al₂O₃, TiO₂, BN, Ta₂O₅, Nb₂O₅, SrTiO₃, BaTiO₃, ZrO₂, HfO₂, or a combination thereof.

Aspect 15: The coated polymer composition of any of aspects 1-14, wherein the inorganic material comprises silica.

Aspect 16: The coated polymer composition of any of aspects 1-15, wherein the inorganic material comprises a titanium oxide, boron nitride, niobium oxide, strontium titanate, barium titanate, hafnium oxide, or a combination thereof.

Aspect 17: The coated polymer composition of any of aspects 1-16, wherein the polymer substrate has a thickness of from about 1 μm to about 50 μm.

Aspect 18: The coated polymer composition of any of aspects 1-17, wherein the polymer substrate has a thickness of about 5 μm.

Aspect 19: The coated polymer composition of any of aspects 1-18, wherein the inorganic material has a thickness of from about 20 nm to about 100 nm.

Aspect 20: The coated polymer composition of any of aspects 1-19, having a dielectric strength at least 30% higher than a comparable uncoated polymer substrate.

Aspect 21: The coated polymer composition of any of aspects 1-19, having a dielectric strength at least 40% higher than a comparable uncoated polymer substrate.

Aspect 22: The coated polymer composition of any of aspects 1-19, having a dielectric strength at least 45% higher than a comparable uncoated polymer substrate.

Aspect 23: The coated polymer composition of any of aspects 1-22, wherein the inorganic material is disposed on a first surface of the polymer substrate and a second inorganic material is disposed on an opposing surface of the polymer substrate.

Aspect 24: The coated polymer composition of any of aspects 1-23, wherein the inorganic material and the second inorganic material have the same composition.

Aspect 25: The coated polymer composition of any of aspects 1-24, being capable of film winding.

Aspect 26: The coated polymer composition of any of aspects 1-25, wherein the inorganic coating does not adversely affect tensile strength and/or elastic modulus of the composition.

Aspect 27: A coated polymer composite, comprising a) a polymer substrate comprising a polymer and one or more composite additives; and b) an inorganic material present on at least one surface of the polymer substrate, wherein the coated polymer composite has an improved dielectric strength as compared to an uncoated polymer composite of the same composite.

Aspect 28: The coated polymer composite of aspect 27, wherein the composite additive comprises BaTiO₃, SiO₂, Si₃N₄, Al₂O₃, TiO₂, BN, Ta₂O₅, Nb₂O₅, SrTiO₃, ZrO₂, HfO₂, or a combination thereof. Aspect 27: In one aspect of aspect 24, the composite additive comprises BaTiO₃.

Aspect 28a: The coated polymer composite of aspects 27 or 28, wherein the inorganic material comprises an inorganic material with a high dielectric constant.

Aspect 29: The coated polymer composite of any of aspects 27-28a, wherein the polymer substrate comprises polymethylmethacrylate, polyvinyl chloride, nylon, polyethylene terephthalate, polyimide, polyetherimide, polytetrafluoroethylene, polyethylene, polypropylene, polycarbonate, polystyrene, polysulfone, or a combination thereof.

Aspect 30: The coated polymer composite of any of aspects 27-29, wherein the polymer substrate comprises polyetherimide.

Aspect 31: The coated polymer composite of any of aspects 27-30, wherein the polyetherimide has the structure represented by a formula:

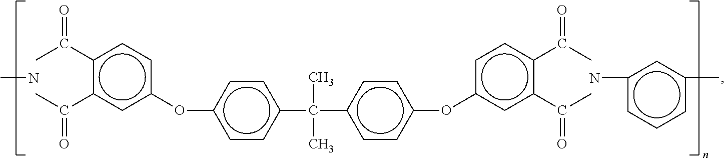

wherein the polyetherimide polymer has a molecular weight of at least 20,000 Daltons.

Aspect 32: The coated polymer composite of any of aspects 27-29, wherein the polymer substrate comprises a polycarbonate.

Aspect 33: The coated polymer composite of claim any of aspects 27-29 or 32, wherein the polycarbonate comprises the formula:

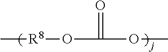

wherein at least about 60 percent of the total number of R⁸ groups are aromatic organic radicals and the balance thereof are aliphatic, alicyclic, or aromatic radicals, wherein j is at least 2.

Aspect 34: The coated polymer composite of any of aspects 27-33, wherein the polymer substrate does not comprise a cyano functionalized polymer.

Aspect 35: The coated polymer composite of any of aspects 27-34, wherein the polymer substrate does not comprise a polyetherimide derived from a cyano modified polyetherimide.

Aspect 36: The coated polymer composite of claim any of aspects 27-35, wherein the inorganic material is present on opposing sides of the polymer substrate.

Aspect 37: The coated polymer composite of any of aspects 27-36, wherein the inorganic material comprises an inorganic material with a low dielectric constant.

Aspect 38: The coated polymer composite of aspect 37, wherein the inorganic material present on both opposing sides comprises an inorganic material with a low dielectric constant.

Aspect 39: The coated polymer composite of any of aspects 27-38, wherein the inorganic material comprises an inorganic material with a high dielectric constant and an inorganic material with a low dielectric constant.

Aspect 40: The coated polymer composite of any of aspects 27-39, wherein the inorganic material comprises SiO₂, Si₃N₄, Al₂O₃, TiO₂, BN, Ta₂O₅, Nb₂O₅, SrTiO₃, BaTiO₃, ZrO₂, HfO₂, or a combination thereof.

Aspect 41: The coated polymer composite of any of aspects 27-40, wherein the inorganic material comprises silica.

Aspect 42: The coated polymer composite of claim any of aspects 27-41, wherein the inorganic material comprises a titanium oxide, boron nitride, niobium oxide, strontium titanate, barium titanate, hafnium oxide, or a combination thereof.

Aspect 43: The coated polymer composite of any of aspects 27-42, wherein the polymer substrate has a thickness of from about 1 μm to about 50 μm.

Aspect 44: The coated polymer composite of any of aspects 27-43, wherein the polymer substrate has a thickness of about 5 μm.

Aspect 45: The coated polymer composite of any of aspects 27-44, wherein the inorganic material has a thickness of from about 20 nm to about 200 nm.

Aspect 46: The coated polymer composite of any of aspects 27-45, having a dielectric strength at least 30% higher than a comparable uncoated polymer substrate.

Aspect 47: The coated polymer composite of any of aspects 27-46, having a dielectric strength at least 40% higher than a comparable uncoated polymer substrate.

Aspect 48: The coated polymer composite of any of aspects 27-47, having a dielectric strength at least 45% higher than a comparable uncoated polymer substrate.

Aspect 49: The coated polymer composite of any of aspects 27-48, wherein the inorganic material is disposed on a first surface of the polymer substrate and a second inorganic material is disposed on an opposing surface of the polymer substrate.

Aspect 50: The coated polymer composite of any of aspects 27-49, wherein the inorganic material and the second inorganic material have the same composition.

Aspect 51: The coated polymer composite of any of aspects 27-50, being capable of film winding.

Aspect 52: The coated polymer composite of any of aspects 27-51, wherein the inorganic coating does not adversely affect tensile strength and/or elastic modulus of the composition.

Aspect 53: An electronic component comprising the coated polymer composition of any of aspects 1-51.

Aspect 54: A capacitor comprising the coated polymer composition of any of aspects 1-51.

Aspect 55: A method of preparing a coated polymer composition, the method comprising depositing an inorganic material on at least a portion of one surface of a polymer substrate, such that the resulting coated polymer composition has an improved dielectric strength over the polymer substrate itself.

Aspect 56: The method of aspect 55, wherein the deposition is performed via sputtering, chemical vapor deposition, plasma enhanced chemical vapor deposition, atomic layer deposition, or a combination thereof.

Aspect 57: The method of aspects 55 or 56, wherein the polymer substrate comprises polymethylmethacrylate, polyvinyl chloride, nylon, polyethylene terephthalate, polyimide, polyetherimide, polytetrafluoroethylene, polyethylene, polypropylene, polycarbonate, polystyrene, polysulfone, or a combination thereof.

Aspect 58: The method of aspects 57, wherein the polymer substrate comprises polyetherimide.

Aspect 59: The method of aspects 56 or 57, wherein the polyetherimide has the structure represented by a formula:

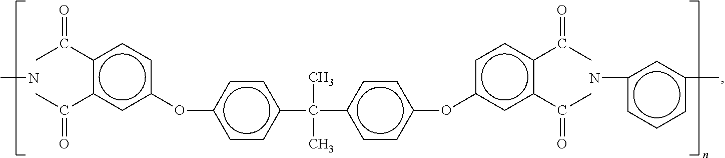

wherein the polyetherimide polymer has a molecular weight of at least 20,000 Daltons.

Aspect 60: The method of any of aspects 55-57, wherein the polymer substrate comprises a polycarbonate.

Aspect 61: The method of aspects 57 or 60, wherein the polycarbonate comprises the formula:

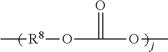

wherein at least about 60 percent of the total number of R⁸ groups are aromatic organic radicals and the balance thereof are aliphatic, alicyclic, or aromatic radicals, wherein j is at least 2.

Aspect 62: The method of any of aspects 55-61, wherein the polymer substrate does not comprise a cyano functionalized polymer.

Aspect 63: The method of any of aspects 55-62, wherein the polymer substrate does not comprise a polyetherimide derived from a cyano modified polyetherimide.

Aspect 64: The method of any of aspects 55-63, wherein the inorganic material is deposited in a single layer on a single surface of the polymer substrate.

Aspect 65: The method of any of aspects 55-64, wherein the inorganic material comprises SiO₂, Si₃N₄, Al₂O₃, TiO₂, BN, Ta₂O₅, Nb₂O₅, BaTiO₃, SrTiO₃, ZrO₂, HfO₂, or a combination thereof.

Aspect 66: The method of any of aspects 55-65, wherein the inorganic material comprises a titanium oxide, boron nitride, niobium oxide, strontium titanate, barium titanate, hafnium oxide, or a combination thereof.

Aspect 67: The method of any of aspects 55-66, wherein the inorganic material comprises silica.

Aspect 68: The method of any of aspects 55-67, wherein the polymer substrate has a thickness of from about 1 μm to about 50 μm.

Aspect 69: The method of any of aspects 55-68, wherein the polymer substrate has a thickness of about 5 μm.

Aspect 70: The method of any of aspects 55-69, wherein the inorganic material is deposited to a thickness of from about 20 nm to about 100 nm.

Aspect 71: The method of any of aspects 55-70, further comprising depositing a second inorganic material on an opposing surface of the polymer substrate.

Aspect 72: The method of any of aspects 55-71, wherein the inorganic material and the second inorganic material have the same composition.

Aspect 73: The coated polymer composition of aspects 5 and 6, wherein the polycarbonate comprises a bisphenol.

Aspect 74: The coated polymer composition of aspects 5, 6, and 73, wherein the bisphenol comprises a phthalimidine carbonate unit.

Aspect 75: The coated polymer composition of aspects 1, 5, 6, 73, and 74, wherein the polymer substrate comprises a polymer carbonate.

While typical aspects have been set forth for the purpose of illustration, the foregoing descriptions should not be deemed to be a limitation on the scope of the invention. Accordingly, various modifications, adaptations, and alternatives can occur to one skilled in the art without departing from the spirit and scope of the present invention.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

5. Preparation of Silica Coating on Polyetherimide Film

In a first example, 100 nm thick films of SiO₂ were deposited on samples of Ultem® polyetherimide film. A baseline deposition was performed at a pressure of 5 mTorr and with an Ar:O₂ ratio of 40:2.5 (sccm). A high pressure deposition was performed at a pressure of 15 mTorr and an Ar:O₂ ratio of 40:2.5 (sccm). A low oxygen deposition was performed at a pressure of 5 mTorr and an Ar:O₂ ratio of 40:0 (sccm). An oxygen rich deposition was also performed at a pressure of 5 mTorr and an Ar:O₂ ratio of 40:7.5 (sccm).

6. Polymer Substrate Thickness

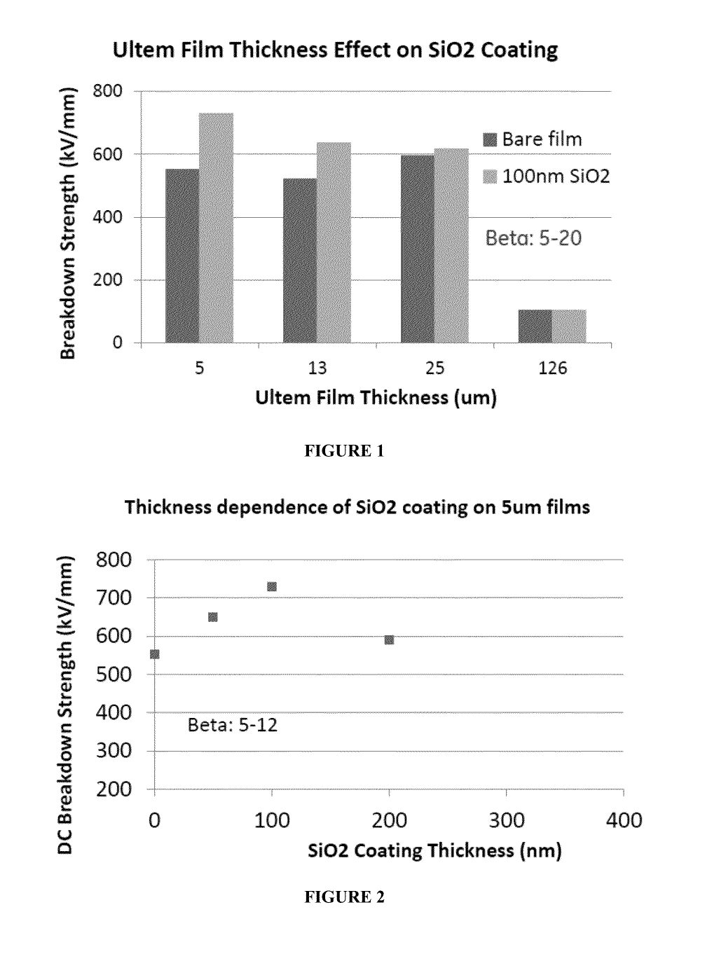

In a second example, 100 nm thick films of SiO₂ were deposited on Ultem® polyetherimide samples of varying thickness. The resulting electrical breakdown strength (kV/mm) of each sample was then determined, as illustrated in FIG. 1. Each of the 5 μm, 13 μm, and 25 μm thick polyetherimide films exhibited significant increase in electrical breakdown strength after deposition of a 100 nm thick silica film (as compared to a bare uncoated film).

7. Inorganic Coating Thickness

In a third example, silica film of varying thickness were deposited on 5 μm thick polyetherimide films. The resulting DC breakdown strength was determined for each sample, as illustrated in FIG. 2. The breakdown strength of each of the coated films was measurable increased over the uncoated film. The sample with a 100 nm thick silica coating exhibited the highest breakdown strength, followed by a sample with a 50 nm thick coating, and a sample with a 200 nm thick coating sample.

8. Inorganic Coating Thickness

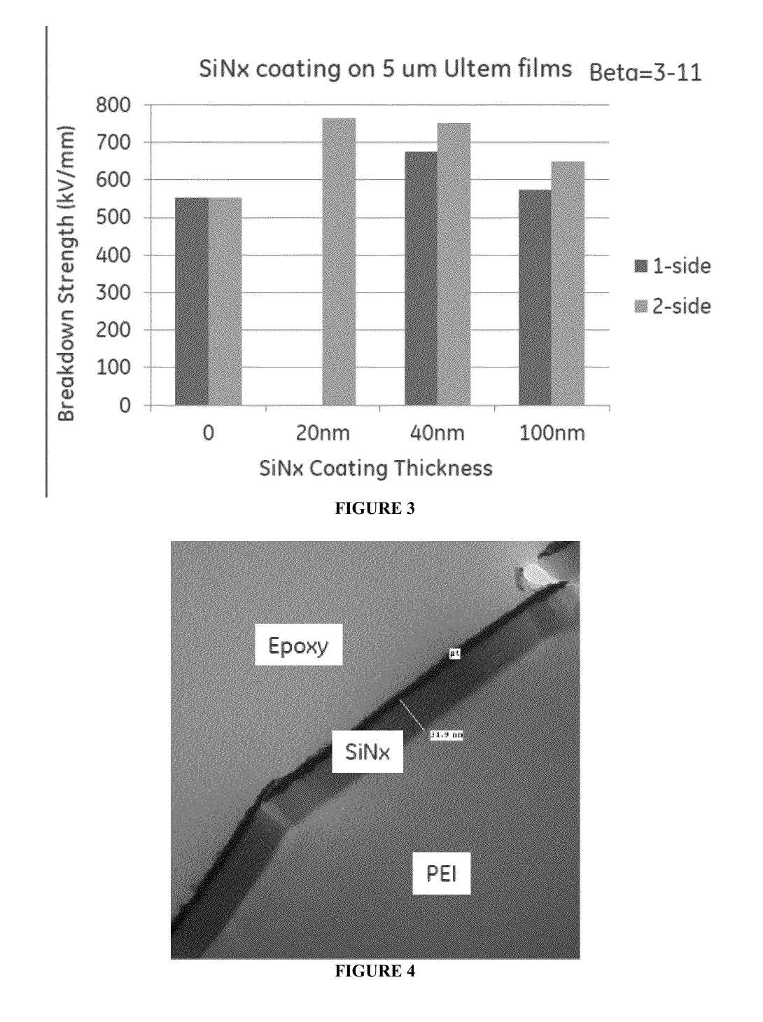

In a fourth example, silicon nitrde (SiNₓ) film of varying thickness were deposited on one and both sides of 5 μm thick polyetherimide films. A double sided 20 nm SiNₓ coating was sufficient to significantly increase the breakdown strength of the resulting coated film. As illustrated in FIG. 3, a double sided 40 nm thick SiNₓ coating provided comparable performance to the double sided 20 nm thick coating. A single sided 40 μm thick SiNₓ coating provided improved breakdown strength, but was slightly lower than the comparable double sided coating. Similarly, single and double sided 100 nm thick SiNₓ coatings provided improvements in breakdown strength as compared to an uncoated polyetherimide film.

9. Inorganic Coating Thickness

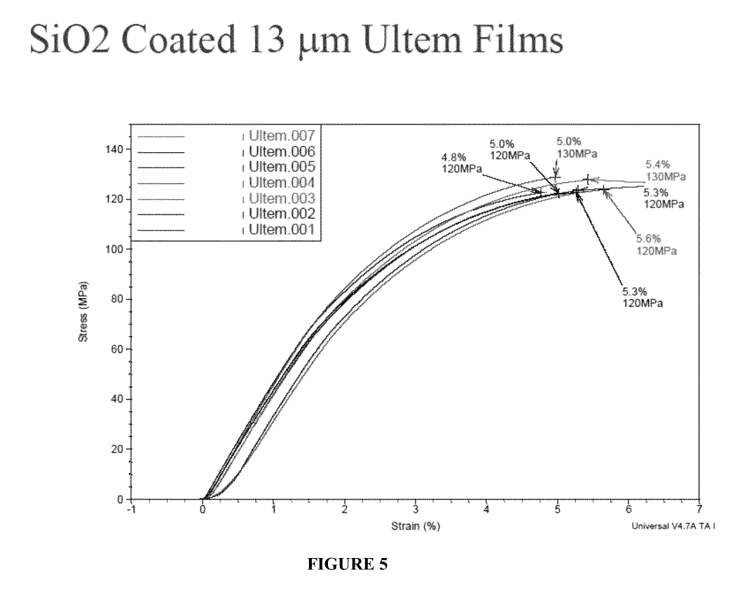

In a fifth example, stress strain curves were measured for silica coated 13 μm Ultem® polyetherimide films. FIG. 5 illustrates the room temperature tensile behavior of coated and uncoated films. The tensile strength for the coated films is about 17 ksi, indicating that the coating does not adversely affect the mechanical strength of the underlying polyetherimides film. The elastic modulus for coated film is about 500 ksi, higher than that for a base polyetherimides film. These properties indicate the suitability of the inventive materials for film winding. In contrast conventional highly loaded nanocomposite films exhibit adverse changes in tensile strength and elastic modulus.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

10. Performance and Breakdown Strength of Ultem 1000 Polymer Substrates Coated with Inorganic Material

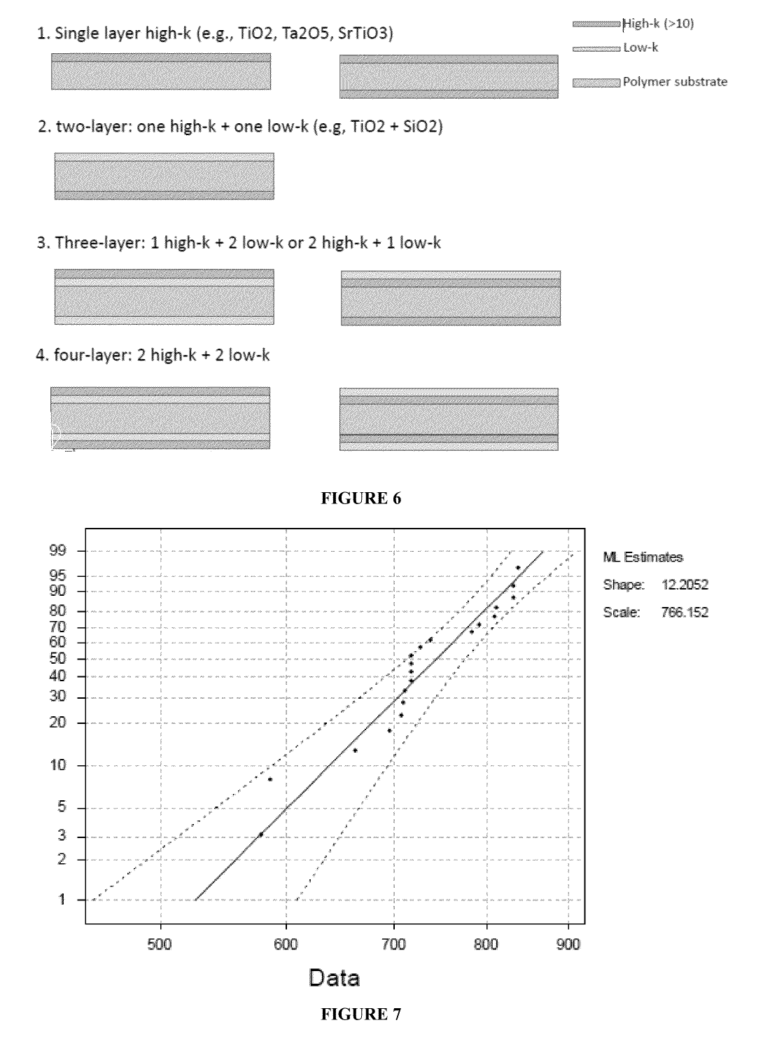

Various schemes for coating inorganic materials on a polymer substrate can be utilized, as illustrated in, for example, FIG. 6. Such schemes can include: Scheme 1A—a polymer substrate having an inorganic material with a high dielectric constant present on a single side thereof; Scheme 1B—a polymer substrate having an inorganic material with a high dielectric constant present on opposing sides thereof; Scheme 2—a polymer substrate having an inorganic material with a high dielectric constant present on one side thereof and an inorganic material with a low dielectric constant is present on the opposing side thereof Scheme 3A—a polymer substrate having an inorganic material with a low dielectric constant on opposing sides thereof (i.e., in contact with the polymer substrate), wherein one side additionally has an inorganic material with a high dielectric constant in contact with the inorganic material having a low dielectric constant (i.e., not in contact with the polymer substrate); Scheme 3B—a polymer substrate having an inorganic material with a high dielectric constant on opposing sides thereof (i.e., in contact with the polymer substrate), wherein one side additionally has an inorganic material with a low dielectric constant in contact with the inorganic material having a high dielectric constant (i.e., not in contact with the polymer substrate); Scheme 4A—a polymer substrate having an inorganic material with a low dielectric constant on opposing sides thereof (i.e., in contact with the polymer substrate) and additionally an inorganic material having a high dielectric constant in contact with each of the low dielectric inorganic materials (i.e., not in contact with the polymer substrate); or Scheme 4B—a polymer substrate having an inorganic material with a high dielectric constant on opposing sides thereof (i.e., in contact with the polymer substrate) and additionally an inorganic material having a low dielectric constant in contact with each of the high dielectric inorganic materials (i.e., not in contact with the polymer substrate). Table 1 shows the breakdown strength of polymers coated with different inorganic materials.

TABLE 1
Breakdown strengths at various sputtering conditions
Inorganic coating enhanced dielectric properties of polymer films
Sputtering Condition (breakdown strength in kV/mm)

| | | | | Magen- | Magne- | Magne | Magne |
|---|---|---|---|---|---|---|---|
| Coating | Coating | Reactive | Reactive | tron at | tron at | tron at | tron at |
| Scheme | material | at 7% O2 | at 18% O2 | 0% O2 | 7% O2 | 10% O2 | 18% O2 |
| Ultem | None | 551.9 | | | | | |
| baseline | | | | | | | |
| Low-K | SiO2 (100 nm) | 713.9 | 544.5 | 799.5 | 647.5 | | |
| coating | | | | | | | |
| Scheme-1B | Ta2O5 (100 nm) | 701.3 | 766.2 | | | | |
| Scheme-1B | SrTiO3 (100 nm) | | | 702.7 | | 636 | |
| Scheme-1B | TiO2 (100 nm) | | 595.1 | | 331.7 | | 584.8 |
| Scheme-1B | TiO2 (50 nm) | 552.5 | | 346.8 | | | |
| Scheme-2 | SiO2 (100 nm)- | | | | 604.6 | | |
| | Ta2O5 (50 nm) | | | | | | |
| Scheme-2 | SiO2 (100 nm)- | | | | | | 628.6 |
| | Ta2O5 (100 nm) | | | | | | |
| Scheme-2 | SiO2 (100 nm)- | | | 698.5 | | | |
| | SrTiO3 (100 nm) | | | | | | |
| Scheme-3A | SrTiO3 (100 nm)- | | | 624 | | | |
| | SiO2 (50 nm) | | | | | | |
| Scheme-3A | SrTiO3 (100 nm)- | | | 711.1 | | | |
| | SiO2 (100 nm) | | | | | | |
| Scheme-4A | Ta2O5 (50 nm)- | | | | | | 656.5 |
| | SiO2 (100 nm) | | | | | | |
| Scheme-4A | Ta2O5 (100 nm)- | | | | | | 689.2 |
| | SiO2 (100 nm) | | | | | | |
| Scheme-4A | SrTiO3 (100 nm)- | | | 693.1 | | | |
| | SiO2 (50 nm) | | | | | | |
| PC baseline | None | 700.5 | | | | | |
| Scheme-1B | Ta2O5 (50 nm) | | | | | | 823.3 |
| | on PC | | | | | | |
| Scheme-1B | Ta2O5 (100 nm) | | | | | | 799.6 |
| | on PC | | | | | | |
| Ultem- | None | 182 | | | | | |
| 30 wt % | | | | | | | |
| BaTiO3 | | | | | | | |
| Scheme-1B | SiO2 (100 nm) | | | 211.8 | | | |

The various configuration of coating schemes can be seen in FIG. 6.

FIG. 7 indicates that a higher oxygen flow rate is required during reactive sputtering Ta₂O₅ due to the high atomic weight of Ta₂O₅.

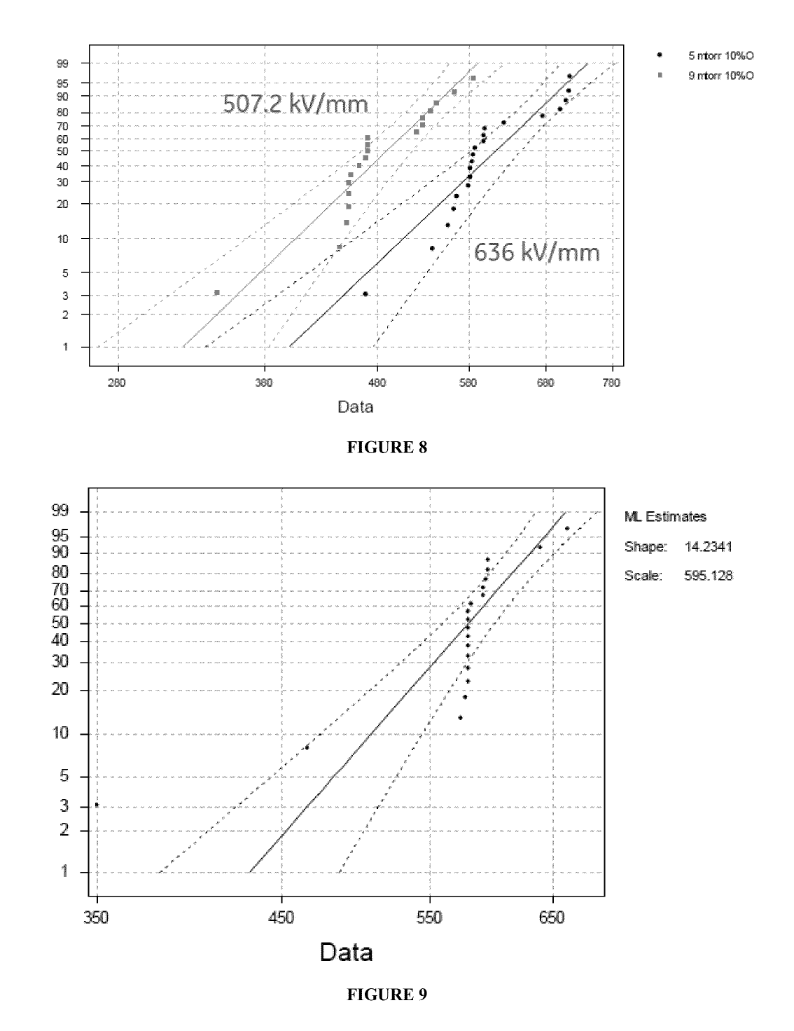

FIG. 8 indicates that lower pressure during the deposition of SrTiO₃ increased the breakdown strength. 5 mTorr pressure yielded a breakdown strength of 636 kV/mm while 9 mTorr pressure yielded a breakdown strength of 507.2 kV/mm.

FIG. 9 indicates that reactive sputtering of TiO₂ with 18% O₂ increased the breakdown strength of a 5 μm thick Ultem film.

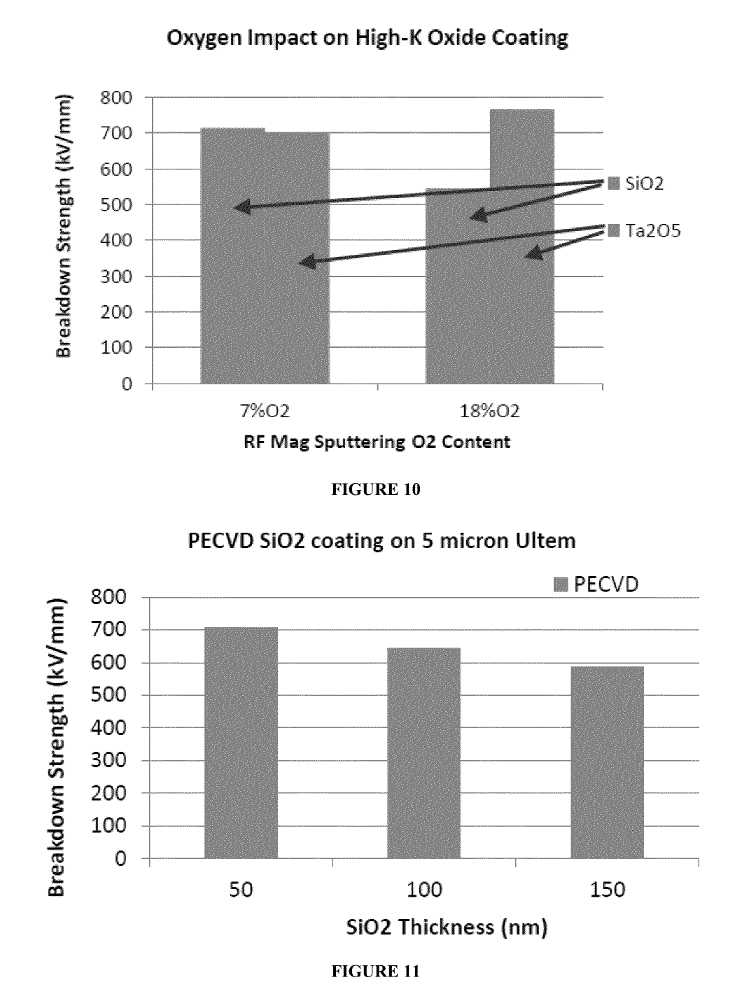

FIG. 10 indicates that a higher oxygen concentration decreases the breakdown strength of a 5 μm thick Ultem film during the deposition of SiO₂. FIG. 10 also indicates that a higher oxygen flow rate increases the breakdown strength of a 5 μm thick Ultem film during the deposition of Ta₂O₅.

FIG. 11 indicates that a 5 μm thick Ultem film with a 50 nm thick SiO₂ layer has higher breakdown strength than a 5 μm thick Ultem film with a 100 nm or 150 nm thick SiO₂ layer when the SiO₂ is deposited via PECVD.

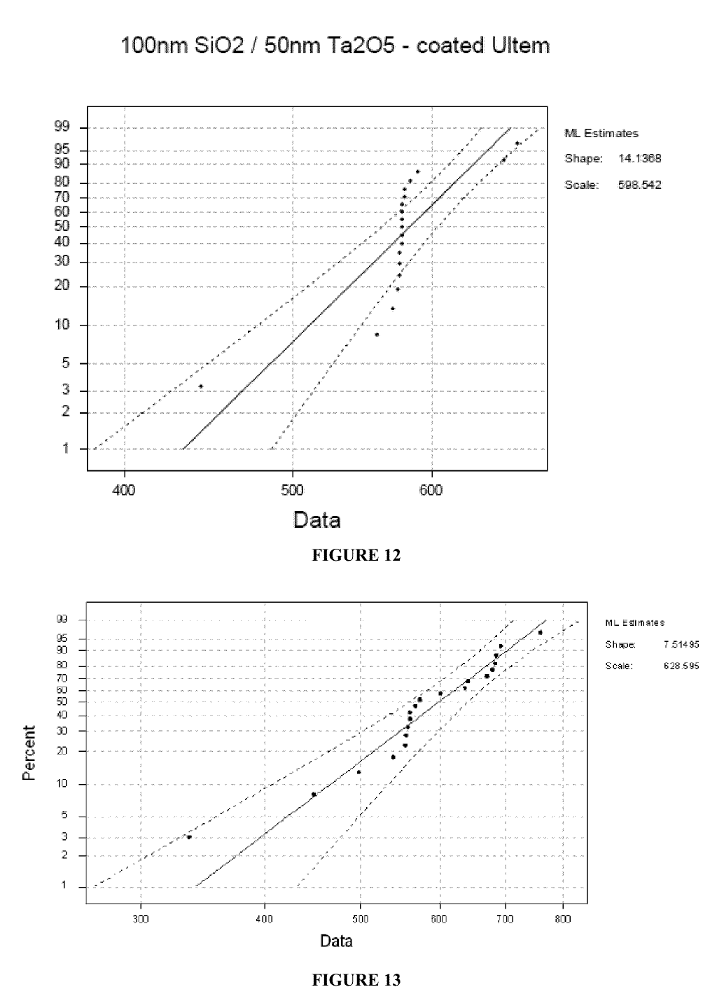

FIG. 12 indicates that combination coating with 50 nm Ta₂O₅ and 100 nm SiO₂ is not as effective as SiO₂ coating alone. FIG. 13 indicates that increasing the thickness of Ta₂O₅ to 100 nm in a combination coating is more effective than 50 nm Ta₂O₅.

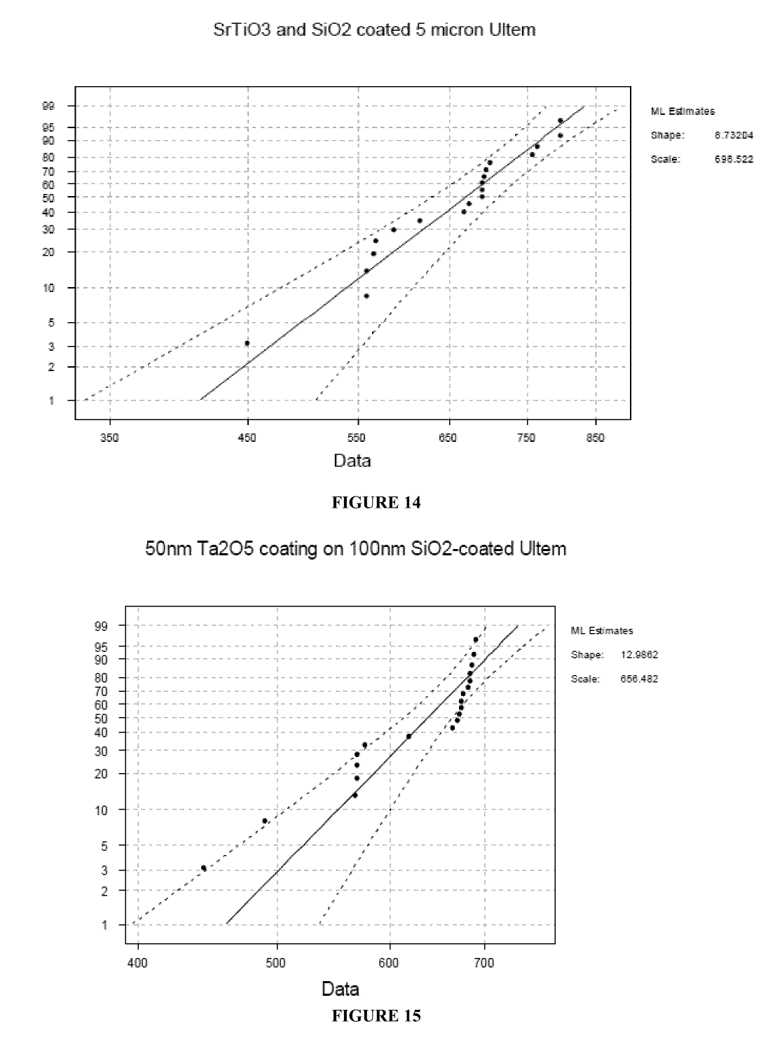

FIG. 14 indicates that combination coating with 100 nm SrTiO₃ and 100 nm SiO₂ is effective in increasing the breakdown strength.

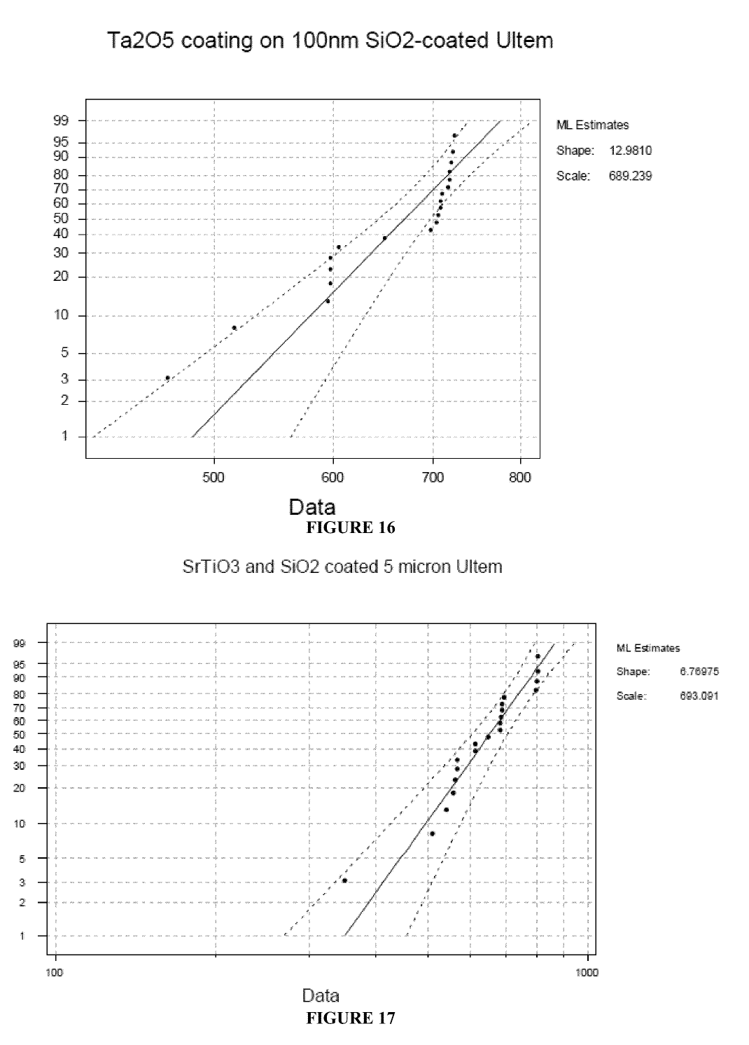

FIGS. 15 and 16 indicate that multilayer coating with 50 nm Ta₂O₅ or 100 nm Ta₂O₅ and 100 nm SiO₂ are effective in increasing the breakdown strength.

FIG. 17 indicates that multilayer coating with 100 nm SrTiO₃ and 50 nm SiO₂ is effective in increasing the breakdown strength.

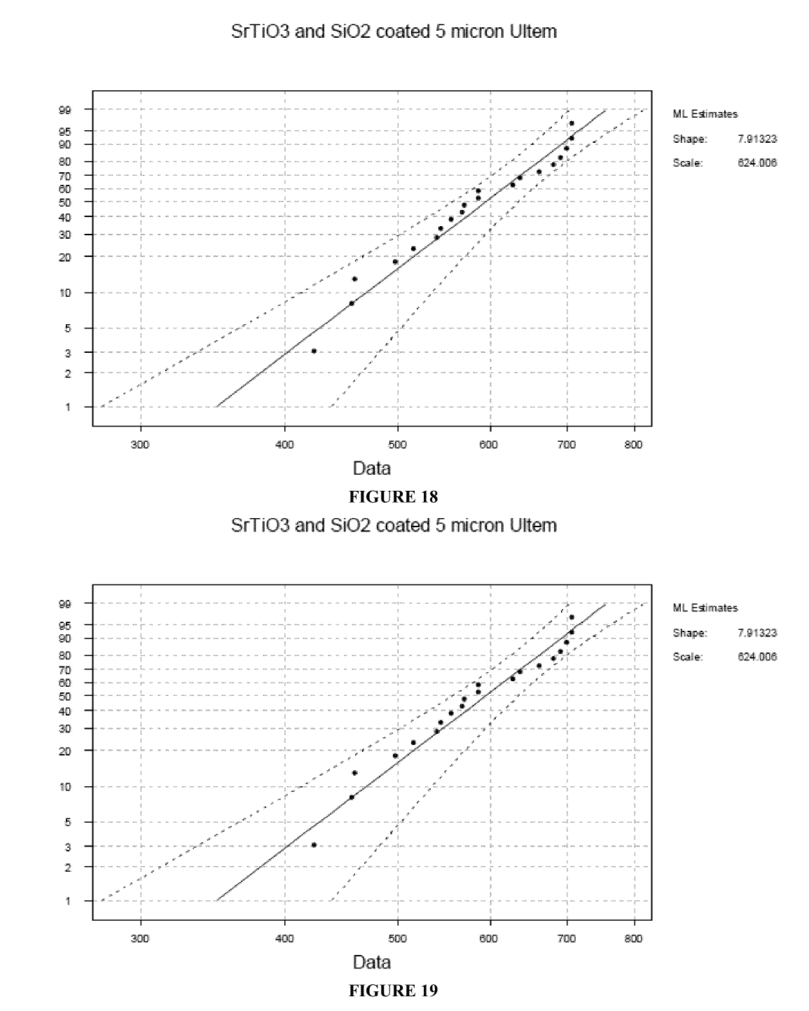

FIG. 18 indicates that multilayer coating on one side of the polymer substrate with 100 nm SrTiO₃ and 50 nm SiO₂ and only 50 nm SiO₂ on the opposing side of the polymer substrate is effective in increasing the breakdown strength.

FIG. 19 indicates that 100 nm of SiO₂ on Ultem-30% BaTiO₃ films increases the breakdown strength.

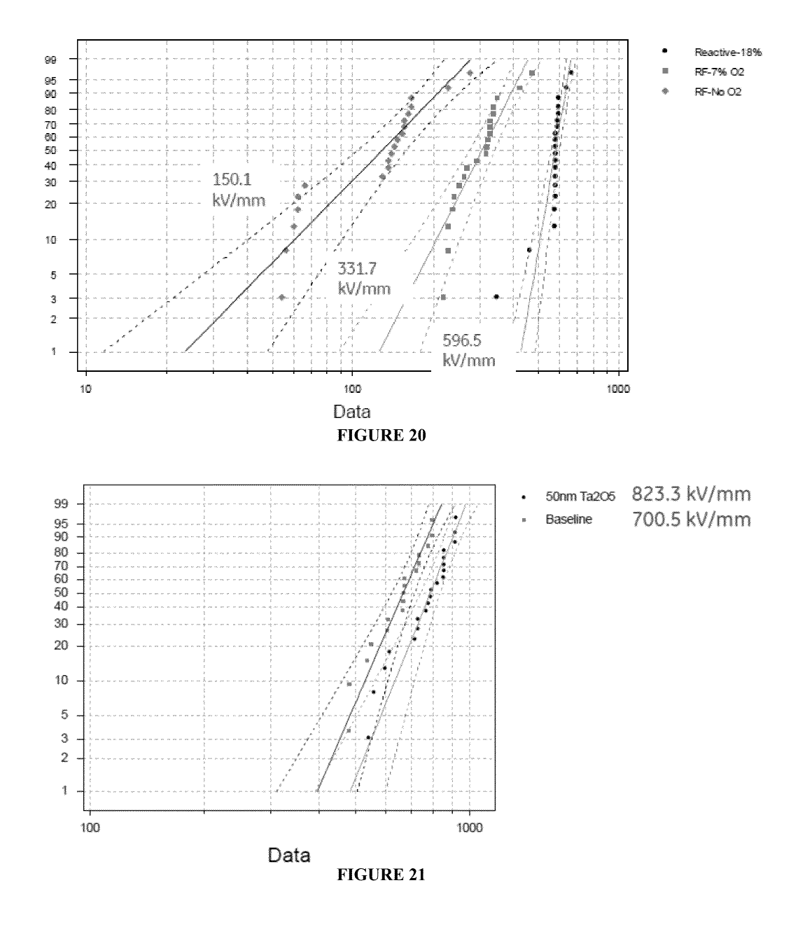

FIG. 20 indicates that reactive sputtering of TiO₂ can increase the breakdown strength of a Ultem film if the TiO₂ is deposited under high (18%) oxygen flow. A low oxygen flow promotes the formation of conductive TiOₓ which leads to a lower breakdown strength.

FIG. 21 indicates that a 50 nm Ta₂O₅ coating on a 10 μm polycarbonate film increases the breakdown strength.

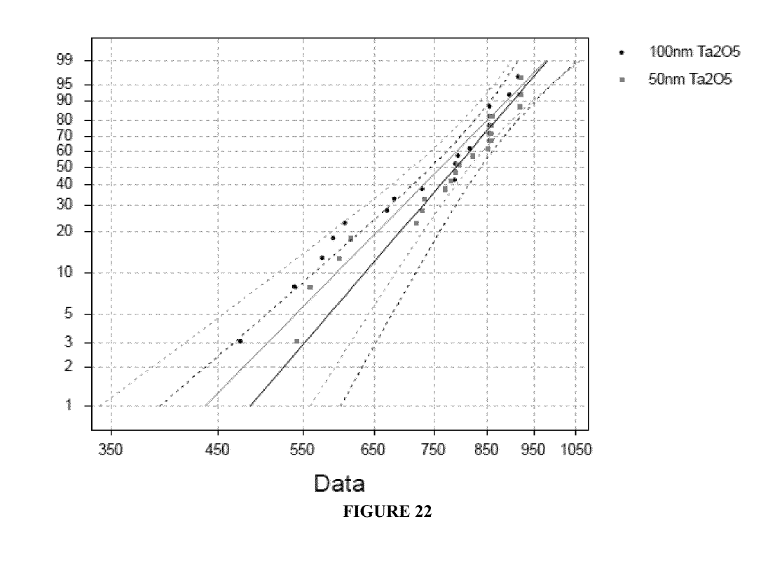

FIG. 22 indicates that both 50 nm and 100 nm coatings of Ta₂O₅ is sufficient to increase the breakdown strength when the Ta₂O₅ is deposited under 18% O₂.

What is claimed is:

1. A coated polymer composition, comprising a polymer substrate and an inorganic material present on at least one surface thereof, wherein the coated polymer composition has an improved dielectric strength as compared to an uncoated polymer substrate of the same composition, wherein the inorganic material has a thickness of about 20 nm to about 200 nm if the inorganic material present on the at least one surface does not comprise a high dielectric inorganic material.

2. The coated polymer composition of claim 1, wherein the inorganic material comprises an inorganic material with a high dielectric constant.

3. The coated polymer composition of claim 1, wherein the polymer substrate comprises polymethylmethacrylate, polyvinyl chloride, nylon, polyethylene terephthalate, polyimide, polyetherimide, polytetrafluoroethylene, polyethylene, ultra-high-molecular-weight polyethylene, polypropylene, polycarbonate, polystyrene, polysulfone, polyamides, aromatic polyamids, polyphenylene sulfide, polybutylene terephthalate, polyphenylene oxide, acrylonitrile butadiene styrene, polyetgerketone, polyetheretherketone, polyoxymethylene plastic, polyvinylidene fluoride, cellulose acetate, or a combination thereof.

4. The coated polymer composition of claim 1, wherein the polymer substrate comprises polyetherimide.

5. The coated polymer composition of claim 4, wherein the polyetherimide has the structure represented by a formula: 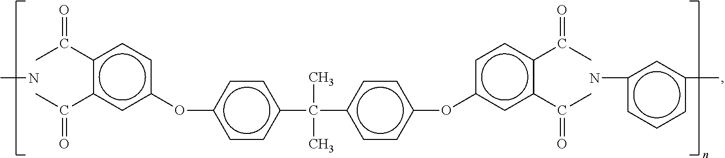
wherein the polyetherimide polymer has a molecular weight of at least 20,000 Daltons.

6. The coated polymer composition of claim 1, wherein the polymer substrate comprises a polycarbonate.

7. The coated polymer composition of claim 6, wherein the polycarbonate comprises the formula: 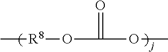
wherein at least about 60 percent of the total number of R⁸ groups are aromatic organic radicals and the balance thereof are aliphatic, alicyclic, or aromatic radicals, wherein j is at least 2.

8. The coated polymer composition of claim 6, wherein the polycarbonate comprises a bisphenol.

9. The coated polymer composition of claim 8, wherein the bisphenol comprises a phthalimidine carbonate unit.

10. The coated polymer composition of claim 1, wherein the polymer substrate comprises a polyester carbonate.

11. The coated polymer composition of claim 1, wherein the polymer substrate does not comprise a cyano functionalized polymer.

12. The coated polymer composition of claim 1, wherein the polymer substrate does not comprise a polyetherimide derived from a cyano modified polyetherimide.

13. The coated polymer composition of claim 1, wherein the inorganic material is present on opposing sides of the polymer substrate.

14. The coated polymer composition of claim 1, wherein the inorganic material comprises an inorganic material with a low dielectric constant.

15. The coated polymer composition of claim 13, wherein the inorganic material present on both opposing sides comprises an inorganic material with a low dielectric constant.

16. The coated polymer composition of claim 1, wherein the inorganic material comprises an inorganic material with a high dielectric constant and an inorganic material with a low dielectric constant.

17. The coated polymer composition of claim 1, wherein the inorganic material comprises SiO₂, Si₃N₄, Al₂O₃, TiO₂, BN, Ta₂O₅, Nb₂O₅, SrTiO₃, BaTiO₃, ZrO₂, HfO₂, or a combination thereof.

18. The coated polymer composition of claim 1, wherein the inorganic material comprises silica.

19. The coated polymer composition of claim 1, wherein the inorganic material comprises a titanium oxide, boron nitride, niobium oxide, strontium titanate, barium titanate, hafnium oxide, or a combination thereof.

20. The coated polymer composition of claim 1, wherein the polymer substrate has a thickness of from about 1 μm to about 50 μm.

21. The coated polymer composition of claim 1, wherein the polymer substrate has a thickness of about 5 μm.

22. The coated polymer composition of claim 1, wherein the inorganic material has a thickness of from about 20 nm to about 100 nm.

23. The coated polymer composition of claim 1, having a dielectric strength at least 30% higher than a comparable uncoated polymer substrate.

24. The coated polymer composition of claim 1, having a dielectric strength at least 40% higher than a comparable uncoated polymer substrate.

25. The coated polymer composition of claim 1, having a dielectric strength at least 45% higher than a comparable uncoated polymer substrate.

26. The coated polymer composition of claim 1, wherein the inorganic material is disposed on a first surface of the polymer substrate and a second inorganic material is disposed on an opposing surface of the polymer substrate.

27. The coated polymer composition of claim 26, wherein the inorganic material and the second inorganic material have the same composition.

28. The coated polymer composition of claim 1, being capable of film winding.

29. The coated polymer composition of claim 1, wherein the inorganic coating does not adversely affect tensile strength and/or elastic modulus of the composition.

30. A coated polymer composite, comprising
a. a polymer substrate comprising a polymer and one or more composite additives; and
b. an inorganic material present on at least one surface of the polymer substrate, wherein the coated polymer composite has an improved dielectric strength as compared to an uncoated polymer composite of the same composite.

31. The coated polymer composite of claim 30, wherein the composite additive comprises BaTiO₃, SiO₂, Si₃N₄, Al₂O₃, TiO₂, BN, Ta₂O₅, Nb₂O₅, SrTiO₃, ZrO₂, HfO₂, or a combination thereof.

32. The coated polymer composite of claim 30, wherein the composite additive comprises BaTiO₃

33. The coated polymer composite of claim 30, wherein the inorganic material comprises an inorganic material with a high dielectric constant.

34. The coated polymer composite of claim 30, wherein the polymer substrate comprises polymethylmethacrylate, polyvinyl chloride, nylon, polyethylene terephthalate, polyimide, polyetherimide, polytetrafluoroethylene, polyethylene, ultra-high-molecular-weight polyethylene, polypropylene, polycarbonate, polystyrene, polysulfone, polyamides, aromatic polyamids, polyphenylene sulfide, polybutylene terephthalate, polyphenylene oxide, acrylonitrile butadiene styrene, polyetgerketone, polyetheretherketone, polyoxymethylene plastic, polyvinylidene fluoride, cellulose acetate, or a combination thereof.

35. The coated polymer composite of claim 30, wherein the polymer substrate comprises polyetherimide.

36. The coated polymer composite of claim 35, wherein the polyetherimide has the structure represented by a formula: 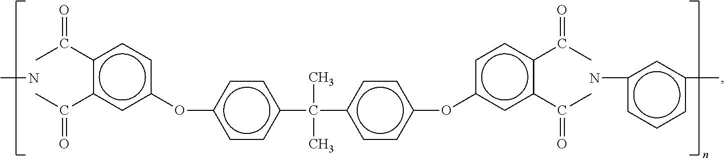
wherein the polyetherimide polymer has a molecular weight of at least 20,000 Daltons.

37. The coated polymer composite of claim 30, wherein the polymer substrate comprises a polycarbonate.

38. The coated polymer composite of claim 37, wherein the polycarbonate comprises the formula: 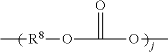
wherein at least about 60 percent of the total number of R⁸ groups are aromatic organic radicals and the balance thereof are aliphatic, alicyclic, or aromatic radicals, wherein j is at least 2.

39. The coated polymer composite of claim 30, wherein the polymer substrate does not comprise a cyano functionalized polymer.

40. The coated polymer composite of claim 30, wherein the polymer substrate does not comprise a polyetherimide derived from a cyano modified polyetherimide.

41. The coated polymer composite of claim 30, wherein the inorganic material is present on opposing sides of the polymer substrate.

42. The coated polymer composite of claim 30, wherein the inorganic material comprises an inorganic material with a low dielectric constant.

43. The coated polymer composite of claim 42, wherein the inorganic material present on both opposing sides comprises an inorganic material with a low dielectric constant.

44. The coated polymer composite of claim 30, wherein the inorganic material comprises an inorganic material with a high dielectric constant and an inorganic material with a low dielectric constant.

45. The coated polymer composite of claim 30, wherein the inorganic material comprises SiO₂, Si₃N₄, Al₂O₃, TiO₂, BN, Ta₂O₅, Nb₂O₅, SrTiO₃, BaTiO₃, ZrO₂, HfO₂, or a combination thereof.

46. The coated polymer composite of claim 30, wherein the inorganic material comprises silica.

47. The coated polymer composite of claim 30, wherein the inorganic material comprises a titanium oxide, boron nitride, niobium oxide, strontium titanate, barium titanate, hafnium oxide, or a combination thereof.

48. The coated polymer composite of claim 30, wherein the polymer substrate has a thickness of from about 1 μm to about 50 μm.

49. The coated polymer composite of claim 30, wherein the polymer substrate has a thickness of about 5 μm.

50. The coated polymer composite of claim 30, wherein the inorganic material has a thickness of from about 20 nm to about 200 nm.

51. The coated polymer composite of claim 30, having a dielectric strength at least 30% higher than a comparable uncoated polymer substrate.

52. The coated polymer composite of claim 30, having a dielectric strength at least 40% higher than a comparable uncoated polymer substrate.

53. The coated polymer composite of claim 30, having a dielectric strength at least 45% higher than a comparable uncoated polymer substrate.

54. The coated polymer composite of claim 30, wherein the inorganic material is disposed on a first surface of the polymer substrate and a second inorganic material is disposed on an opposing surface of the polymer substrate.

55. The coated polymer composite of claim 54, wherein the inorganic material and the second inorganic material have the same composition.

56. The coated polymer composite of claim 30, being capable of film winding.

57. The coated polymer composite of claim 30, wherein the inorganic coating does not adversely affect tensile strength and/or elastic modulus of the composition.

58. An electronic component comprising the coated polymer composition of claim 1.

59. A capacitor comprising the coated polymer composition of claim 1.

60. A method of preparing a coated polymer composition, the method comprising depositing an inorganic material on at least a portion of one surface of a polymer substrate, such that the resulting coated polymer composition has an improved dielectric strength over the polymer substrate itself.

61. The method of claim 60, wherein the deposition is performed via sputtering, chemical vapor deposition, plasma enhanced chemical vapor deposition, atomic layer deposition, or a combination thereof.

62. The method of claim 60, wherein the polymer substrate comprises polymethylmethacrylate, polyvinyl chloride, nylon, polyethylene terephthalate, polyimide, polyetherimide, polytetrafluoroethylene, polyethylene, ultra-high-molecular-weight polyethylene, polypropylene, polycarbonate, polystyrene, polysulfone, polyamides, aromatic polyamids, polyphenylene sulfide, polybutylene terephthalate, polyphenylene oxide, acrylonitrile butadiene styrene, polyetgerketone, polyetheretherketone, polyoxymethylene plastic, polyvinylidene fluoride, cellulose acetate, or a combination thereof.

63. The method of claim 60, wherein the polymer substrate comprises polyetherimide.

64. The method of claim 63, wherein the polyetherimide has the structure represented by a formula: 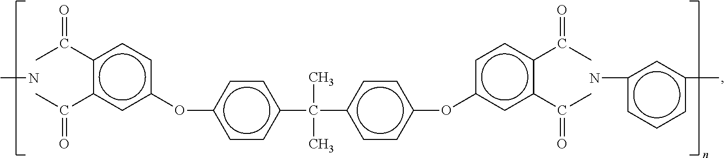
wherein the polyetherimide polymer has a molecular weight of at least 20,000 Daltons.

65. The coated polymer composition of claim 60, wherein the polymer substrate comprises a polycarbonate.

66. The method of claim 65, wherein the polycarbonate comprises the formula: 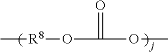
wherein at least about 60 percent of the total number of R⁸ groups are aromatic organic radicals and the balance thereof are aliphatic, alicyclic, or aromatic radicals, wherein j is at least 2.

67. The method of claim 60, wherein the polymer substrate does not comprise a cyano functionalized polymer.

68. The method of claim 60, wherein the polymer substrate does not comprise a polyetherimide derived from a cyano modified polyetherimide.

69. The method of claim 60, wherein the inorganic material is deposited in a single layer on a single surface of the polymer substrate.

70. The method of claim 60, wherein the inorganic material comprises SiO₂, Si₃N₄, Al₂O₃, TiO₂, BN, Ta₂O₅, Nb₂O₅, BaTiO₃, SrTiO₃, ZrO₂, HfO₂, or a combination thereof.

71. The method of claim 60, wherein the inorganic material comprises a titanium oxide, boron nitride, niobium oxide, strontium titanate, barium titanate, hafnium oxide, or a combination thereof.

72. The method of claim 60, wherein the inorganic material comprises silica.

73. The method of claim 60, wherein the polymer substrate has a thickness of from about 1 μm to about 50 μm.

74. The method of claim 60, wherein the polymer substrate has a thickness of about 5 μm.

75. The method of claim 60, wherein the inorganic material is deposited to a thickness of from about 20 nm to about 100 nm.

76. The method of claim 60, further comprising depositing a second inorganic material on an opposing surface of the polymer substrate.

77. The method of claim 76, wherein the inorganic material and the second inorganic material have the same composition.
